(19) United States
(12) Patent Application Publication
(10) Pub. No.: US 2014/0166106 A1
(43) Pub. Date: Jun. 19, 2014

(54) SOLAR CELL BACK-SHEET AND SOLAR CELL MODULE

(71) Applicant: FUJIFILM Corporation, Tokyo (JP)

(72) Inventors: Yuuichi SHIRASAKI, Shizuoka (JP); Shin OZAWA, Shizuoka (JP)

(73) Assignee: FUJIFILM CORPORATION, Tokyo (JP)

(21) Appl. No.: 14/188,983

(22) Filed: Feb. 25, 2014

Related U.S. Application Data
(63) Continuation of application No. PCT/JP2012/072220, filed on Aug. 31, 2012.

(30) Foreign Application Priority Data
Aug. 31, 2011 (JP) 2011-189993

(51) Int. Cl. H01L 31/048

(52) U.S. Cl. CPC H01L 31/0487
USPC 136/256; 136/252

(57) ABSTRACT

Provided is a solar cell backsheet including a polymer base material, and a colored layer that is disposed directly on the polymer base material, and that contains a binder having an acid value of 2 mg KOH/g to 10 mg KOH/g and a pigment at a content of 2.5 g/m² to 8.5 g/m², and that has an adhesive force of 50 N/cm or more to an ethylene-vinyl acetate encapsulating material.

### CROSS-REFERENCE TO RELATED APPLICATIONS

This application is a continuation application of International Application No. PCT/JP/2012/072220, filed Aug. 31, 2012, the disclosure of which is incorporated herein by reference in its entirety. Further, this application claims priority from Japanese Patent Application No. 2011-189993, filed Aug. 31, 2011, the disclosure of which is incorporated herein by reference in its entirety.

### TECHNICAL FIELD

The invention relates to a solar cell backsheet that is provided on the side opposite to the sunlight incidence side of a solar cell element, and a solar cell module.

### BACKGROUND ART

Solar cells represent a power generation system that is free of carbon dioxide emission at the time of power generation and imposes less environmental load, and in recent years, solar cells have rapidly come into wide use.

A solar cell module usually has a structure in which a photovoltaic cell is interposed between a front surface glass plate on the side of sunlight incidence and a so-called backsheet that is disposed on the side opposite to the side of sunlight incidence (back surface side), and the space between the front surface glass plate and the photovoltaic cell and the space between the photovoltaic cell and the backsheet are respectively sealed with an EVA (ethylene-vinyl acetate) resin or the like.

The backsheet is a member having a function of preventing penetration of moisture from the back surface of the solar cell module. Glass, fluorine-based resins and the like have been conventionally used as backsheets, but in recent years, polyesters have come to be used, from the viewpoint of cost. Furthermore, the backsheet may be not only a simple polymer sheet, but may also be a polymer sheet imparted with various functions.

Backsheets usually employ a structure in which layers having other functions are laminated on a polymer base material that serves as a support. Regarding means for laminating functional layers, for example, a method of bonding a polymer sheet having a function that meets a requirement to a support may be used. For example, methods of forming a backsheet by bonding plural resin films using an adhesive have been disclosed (see, for example, Patent Documents: Japanese Patent Application Laid-Open (JP-A) No. 2002-100788 and JP-A No. 2007-128943).

Furthermore, as a method for forming a backsheet at lower cost than in the case of bonding, methods of applying a coating liquid for forming a layer having a function that meets a requirement, on a support (see, for example, Patent Documents JP-A Nos. 2006-210557 and 2003-060218).

### SUMMARY OF INVENTION

An object of the invention is to provide a solar cell backsheet which has designability or reflectiveness, does not easily undergo delamination, has high adhesive force to an sealing material, and exhibits a less decrease in the adhesive force over time that is caused by humidity and heat even after long-term use. Another object of the invention is to provide a solar cell module which can maintain the power generation performance stably over a long time.

Specific means for achieving the objects described above are as follows.

<1> A solar cell backsheet including:

a polymer base material; and

a colored layer that is disposed directly on the polymer base material, contains a binder having an acid value of from 2 mg KOH/g to 10 mg KOH/g and a pigment at a content of from 2.5 g/m² to 8.5 g/m², and has an adhesive force of 50 N/cm or more to an ethylene-vinyl acetate sealing material.

<2> The solar cell backsheet as described in item <1>, wherein the colored layer further contains a structural moiety derived from a crosslinking agent having a content of from 0.5% to 50% by mass with respect to the binder.

<3> The solar cell backsheet as described in item <2>, wherein the crosslinking agent is an oxazoline-based crosslinking agent or a triazine-based crosslinking agent.

<4> The solar cell backsheet as described in any one of items <1> to <3>, wherein at least one layer provided on the polymer base material contains a fluorine-based surfactant.

<5> The solar cell backsheet as described in any one of items <1> to <4>, wherein the pigment is a white pigment, and a reflectance to light having a wavelength of 550 nm is 80% or more on the surface where the colored layer is provided.

<6> The solar cell backsheet as described in any one of items <1> to <5>, wherein when the sealing material and the colored layer are directly bonded and stored for 60 hours in an atmosphere of 120° C. and 100% relative humidity (RH), an adhesive force between the sealing material and the colored layer after storage is 60% or more of an adhesive force between the sealing material and the colored layer before storage, and detachment between the polymer base material and the colored layer does not occur.

<7> The solar cell backsheet as described in any one of items <1> to <6>, wherein the polymer base material contains a polyester resin having a carboxyl group content of 20 equivalents/ton or less.

<8> The solar cell backsheet as described in any one of items <1> to <7>, wherein the polymer base material contains a polyester resin having a carboxyl group content of 17 equivalents/ton or less.

<9> The solar cell backsheet as described in any one of items <1> to <8>, wherein the binder is a polyolefin.

<10> The solar cell backsheet as described in any one of items <1> to <9>, wherein the polymer base material comprises polyethylene terephthalate and an end-capping agent in an amount of from 0.1% by mass to 10% by mass relative to a total mass of polyethylene terephthalate.

<11> The solar cell backsheet as described in any one of items <1> to <10>, wherein the polymer base material contains inorganic particles or organic particles, the particles have an average particle size of from 0.1 μm to 10 μm, and a content of the particles is from 0% to 50% by mass relative to a total mass of the polymer base material.

<12> The solar cell backsheet as described in any one of items <1> to <12>, wherein at least a side of the polymer base material provided with the colored layer is surface-treated by at least one method of a corona treatment, a glow discharge treatment, or flame treatment.

<13> A solar cell module including a solar cell element, an ethylene-vinyl acetate sealing material that seals the solar cell element, a surface protective member that is bonded to the encapsulating material and protects a light-receiving surface side, and a back surface protective member that includes the solar cell backsheet as described in any one of <1> to <12>, has the colored layer bonded directly with the sealing material, and protects an opposite side of the light-receiving surface.

### Advantageous Effects of Invention

According to the invention, a solar cell backsheet which has designability or reflectiveness, does not easily undergo delamination, has a high adhesive force to an encapsulating material, and exhibits a less decrease in adhesive force over time that is caused by humidity and heat even after long-term use, is provided. A solar cell module which is capable of maintaining the power generation performance stably over a long time is also provided.

### DESCRIPTION OF EMBODIMENTS

Hereinafter, embodiments of the invention will be described, but the following embodiments are merely examples of the invention and are not intended to limit the invention. Meanwhile, in the present specification, the term “from . . . to . . . ” that indicates a numerical value range is used to mean to include the numerical values described before and after the term as the lower limit and the upper limit

<Solar Cell Backsheet>

The solar cell backsheet (also referred to as backsheet) of the invention includes a polymer base material, and a colored layer that is disposed directly on the polymer base material, and that contains a binder having an acid value of from 2 mg KOH/g to 10 mg KOH/g and a pigment at a content of from 2.5 g/m² to 8.5 g/m², and that has an adhesive force of 50 N/cm or more to an ethylene-vinyl acetate encapsulating material.

In the solar cell backsheet of the invention, the colored layer containing a particular binder resin and a predetermined amount of a pigment disposed on the polymer base material exhibits excellent light reflectiveness or designability depending on the kind of the pigment. The colored layer containing a particular binder resin and a predetermined amount of a pigment disposed on the polymer base material also functions as an easily adhesive layer having excellent adhesive force to an ethylene-vinyl acetate sealing material (hereinafter, appropriately described as “EVA sealing material” or simply as “sealing material”) that seals a solar cell element, and the back sheet can be maintained stably without causing detachment or the like over time in a high humidity and high temperature environment. Thus, when such a solar cell backsheet is used, the power generation performance can be maintained stably over a long time.

Furthermore, since the solar cell backsheet of the invention is configured such that only the colored layer is disposed between the polymer base material and the EVA encapsulating material, there are fewer interfaces that may undergo detachment, as compared with the case where other layers such as an easily adhesive layer are provided between the colored layer and the polymer base material or between the colored layer and the sealing material, and delamination in a high humidity and high temperature environment can be suppressed.

—Polymer Base Material—

As the polymer base material that serves as a support of the backsheet according to the invention, a polyester is suitably used. The polyester used in the polymer base materials is a linear saturated polyester synthesized from an aromatic dibasic acid or an ester-forming derivative thereof and a diol or an ester-forming derivative thereof. Specific examples of such a polyester include polyethylene terephthalate, polyethylene isophthalate, polybutylene terephthalate, poly(1,4-cyclohexylenedimethylene terephthalate), and polyethylene-2,6-naphthalate. Among these, in view of a balance between mechanical properties and cost, polyethylene terephthalate or polyethylene-2,6-naphthalate is particularly preferred.

The polyester may be a homopolymer, or may be a copolymer. Also, a polyester mixture blended with a small amount of a resin of different kind from polyester, for example, a polyimide, may also be used.

In the invention, when the polyester is polymerized, from the viewpoint of suppressing the carboxyl group content to a predetermined range or less, a Sb-based, Ge-based or Ti-based compound is preferably used as a catalyst, and among them, a Ti-based compound is particularly preferred. In the case of using a Ti-based compound, an embodiment of performing polymerization using a Ti-based compound as a catalyst in an amount in the range of from 1 ppm to 30 ppm, and more preferably from 3 ppm to 15 ppm, is preferred. When the proportion of the Ti-based compound is in the range, the content of terminal carboxyl groups can be adjusted to the range described below, and resistance to hydrolysis of the polymer base material can be maintained low.

For the synthesis of a polyester using a Ti-based compound, for example, methods described in Japanese Patent Application Laid-Open (JP-A) No. H08-301198, Japanese Patent Nos. 2543624, 3335683, 3717380, 3897756, 3962226, 3979866, 3996871, 4000867, 4053837, 4127119, 4134710, 4159154, 4269704, and 4313538 can be applied.

The carboxyl group content of the polyester resin of the polymer base material is preferably 35 equivalents/ton or less, more preferably 20 equivalents/ton or less, and particularly preferably 17 equivalents/ton or less.

When the carboxyl group content of the polyester resin of the polymer base material is 35 equivalents/ton or less, resistance to hydrolysis is retained, and the decrease in strength occurring after a lapse of time under high humidity and high temperature can be suppressed to a low level. The lower limit of the carboxyl group content is desirably set to 2 equivalents/ton, from the viewpoint of retaining the adhesiveness between the polymer base material and the colored layer that is formed on the surface of the polymer base material. Meanwhile, in the present specification, the unit “equivalents/ton” refers to a molar equivalent per 1 ton.

The carboxyl group content (AV) is a value measured by the following method. That is, 0.1 g of a resin is dissolved in 10 ml of benzyl alcohol, subsequently chloroform is added thereto to obtain a mixed solution, and Phenol Red indicator is added dropwise to the mixed solution. The solution is titrated with a standard liquid (0.01 N KOH-benzyl alcohol mixed solution), and thus the terminal carboxyl group content is determined from the amount of dropwise addition.

The carboxyl group content in the polyester can be adjusted by the kind of the polymerization catalyst and the conditions for film forming (film forming temperature or time).

The polyester of the polymer base material in the invention is preferably obtained by solid phase polymerization, after being polymerized. Thus, a preferred carboxyl group content may be achieved thereby. Solid phase polymerization may be carried out by a continuous method (a method including: packing a resin in a tower, causing the resin to be retained slowly for a predetermined time while heating the resin, and then sending out the resin), or may be carried out by a batch method (a method including: feeding a resin into a container, and heating the resin for a predetermined time). Specifically, for the solid phase polymerization, methods described in Japanese Patent Nos. 2621563, 3121876, 3136774, 3603585, 3616522, 3617340, 3680523, 3717392, and 4167159 can be applied.

The temperature of the solid phase polymerization is preferably from 170° C. to 240° C., more preferably from 180° C. to 230° C., and even more preferably from 190° C. to 220° C. Furthermore, the solid phase polymerization time is preferably from 5 hours to 100 hours, more preferably from 10 hours to 75 hours, and even more preferably from 15 hours to 50 hours. The solid phase polymerization is preferably carried out in a vacuum or a nitrogen atmosphere.

The polymer base material in the invention is preferably a biaxially stretched film obtained by, for example, performing melt extrusion of the polyester into a film form, subjecting the film to cooling solidification using a casting drum to obtain an unstretched film, stretching the unstretched film along the longitudinal direction at a temperature of from Tg to (Tg+60)° C. one time or two or more times such that the total stretch ratio is 3 times to 6 times, and then stretching the resultant along the width direction at a temperature of from Tg to (Tg+60)° C. such that the stretch ratio is 3 times to 5 times.

A biaxially stretched film that has been further subjected to a heat treatment at from 180° C. to 230° C. for 1 second to 60 seconds as necessary, may also be used.

The thickness of the polymer base material is preferably from about 25 μm to 300 μm, and more preferably from 125 μm to 260 μm. When the thickness of the polymer base material is 25 μm or more, satisfactory mechanical strength is obtained, and when the thickness is 300 μm or less, it is advantageous in view of cost.

The polymer base material is such that as the thickness increases, resistance to hydrolysis is deteriorated, and the polymer base material tends to be unable to withstand long-term use. In this invention, when the thickness is from 120 μm to 300 μm, and the carboxyl group content in the polyester is from 2 equivalents/ton to 20 equivalents/ton, an effect of enhancing durability under higher humidity and higher temperature is provided.

The polymer base material may be subjected, if necessary, to a surface treatment such as a corona treatment, a flame treatment or a glow discharge treatment, at least for the surface on the side where the colored layer is provided.

In the corona discharge treatment, a high frequency and high voltage is applied between a metal roll generally coated with a derivative (dielectric roll) and an electrically insulated electrode to occur dielectric breakdown of the air between the electrodes, and thereby, the air between the electrodes is ionized to generate corona discharge. Then, the corona discharge treatment is performed by passing the polymer base material through this corona discharge.

Regarding preferred treatment conditions used in the invention, a gap clearance between the electrode and the dielectric roll of from 1 mm to 3 mm, a frequency of from 1 kHz to 100 kHz, and an applied energy of from about 0.2 kV·A·min/m² to 5 kV·A·min/m² are preferred.

The glow discharge treatment is a method which is also called a vacuum plasma treatment or a low pressure plasma treatment, and is a method including generating plasma through discharge in a gas (plasma gas) in a low pressure atmosphere, and thereby treating the base material surface. The low pressure plasma used in the treatment in the invention is non-equilibrium plasma that is produced under the condition with a low pressure of the plasma gas. The treatment in the invention is carried out by placing the film to be treated (polymer base material) in this low pressure plasma atmosphere.

As the method of generating plasma in the glow discharge treatment in the invention, methods such as direct current glow discharge, high frequency discharge, and microwave discharge can be utilized. The power supply used for discharge may be a direct current source, or may be an alternating current source. When an alternating current is used, the frequency is preferably in the range of from about 30 Hz to 20 MHz.

In the case of using an alternating current, a frequency for commercial use of 50 Hz or 60 Hz may be used, or a high frequency of from about 10 kHz to 50 kHz may also be used. Also, a method using a high frequency of 13.56 MHz is also preferable.

As the plasma gas that is used in the glow discharge treatment in the invention, an inorganic gas such as oxygen gas, nitrogen gas, steam gas, argon gas or helium gas can be used, and particularly, oxygen gas or a mixed gas of oxygen gas and argon gas is preferred. Specifically, a mixed gas of oxygen gas and argon gas is preferably used. When a mixed gas of oxygen gas and argon gas is used, the ratio of the two gases is preferably such that, as a partial pressure ratio, oxygen gas:argon gas=from about 100:0 to 30:70, and more preferably from about 90:10 to 70:30. Furthermore, a method using the air that enters the treatment vessel by leakage, or a gas such as steam that is emitted from the object to be treated, as the plasma gas, without particularly introducing a gas into the treatment vessel, is also preferable.

As the pressure of the plasma gas, a low pressure at which the non-equilibrium plasma conditions are attained is required. Specifically, the pressure of the plasma gas is preferably in the range of from about 0.005 Torr to 10 Torr (from 0.666 Pa to 1333 Pa), and more preferably in the range of from about 0.008 Torr to 3 Torr (from 1.067 Pa to 400 Pa). When the pressure of the plasma gas is 0.666 Pa or more, a sufficient adhesiveness improving effect is obtained, and when the pressure is 1333 Pa or less, the current increases, and the discharge becoming unstable is suppressed.

The plasma power output may vary with the shape or size of the treatment vessel, the shape of the electrode, and the like, and cannot be defined in an overall manner. However, the power output is preferably from about 100 W to 2500 W, and more preferably about 500 W to 1500 W.

The treatment time of the glow discharge treatment in the invention is preferably from about 0.05 seconds to 100 seconds, and more preferably from about 0.5 seconds to 30 seconds. When the treatment time is 0.05 seconds or more, a sufficient adhesiveness improving effect is obtained, and when the treatment time is 100 seconds or less, deformation or coloration of the film to be treated, and the like can be prevented.

The discharge treatment intensity of the glow discharge treatment in the invention may vary with the plasma power output and the treatment time, the discharge treatment intensity is preferably in the range of from 0.01 kV·A·min/m² to 10 kV·A·min/m², and more preferably from 0.1 kV·A·min/m² to 7 kV·A·min/m².

When the discharge treatment intensity is set to 0.01 kV·A·min/m² or higher, a sufficient adhesiveness improving effect is obtained, and when the discharge treatment intensity is set to 10 kV·A·min/m² or less, the problem of deformation or coloration of the film to be treated can be avoided.

In the glow discharge treatment in the invention, it is also preferable to have the film to be treated, heated in advance. By this method, satisfactory adhesiveness can be obtained in a shorter time as compared with the case where heating is not performed. The heating temperature is preferably in the range of from 40° C. to (softening temperature of the film to be treated+20)° C., and more preferably in the range of from 70° C. to the softening temperature of the film to be treated. When the heating temperature is set to 40° C. or higher, a sufficient adhesiveness improving effect is obtained. Furthermore, when the heating temperature is set to the softening temperature of the film to be treated or lower, sufficient handleability of the film can be secured during the treatment.

As a specific method for increasing the temperature of the film to be treated in a vacuum, heating by an infrared heater, heating by bringing the film to be treated into contact with a hot roll, and the like may be employed.

Examples of the flame treatment include a flame treatment using a flame obtained by introducing a silane compound.

Furthermore, as the polymer base material, a polymer base material having resistance to hydrolysis (weather resistance) enhanced by adding an end-capping agent may be also used.

(End-Capping Agent)

Regarding the polymer base material in the invention, the polyester film may contain a polyester resin, and an end-capping agent in an amount of from 0.1% to 10% by mass relative to the total mass of the polyester resin. The amount of addition of the end-capping agent relative to the total mass of the polyester resin of the polymer base material is more preferably from 0.2% to 5% by mass, and even more preferably from 0.3% to 2% by mass.

Since hydrolysis of polyester is accelerated by the catalytic effect of H⁺ that is produced from terminal carboxylic acid or the like, in order to enhance the resistance to hydrolysis (weather resistance), it is effective to add an end-capping agent which reacts with terminal carboxylic acid.

When the amount of addition of the end-capping agent is 0.1% by mass or more relative to the total mass of the polyester resin, a weather resistance enhancing effect is easily exhibited, and when the amount of addition is 10% by mass or less, the end-capping agent is suppressed from acting as a plasticizer on the polyester, and the decrease in mechanical strength and heat resistance is suppressed.

Examples of the end-capping agent include epoxy compounds, carbodiimide compounds, oxazoline compounds, and carbonate compounds, a carbodiimide that has high affinity with polyethylene terephthalate (PET) and high end-capping ability is preferred.

It is preferable that the end-capping agent (particularly, a carbodiimide end-capping agent) have a high molecular weight. Thus, volatilization during melt film forming can be reduced thereby. The molecular weight is preferably from 200 to 100,000, more preferably from 2000 to 80,000, and even more preferably from 10,000 to 50,000. When the molecular weight of the end-capping agent (particularly, carbodiimide end-capping agent) is in the range described above, the end-capping agent can be easily dispersed uniformly in the polyester, and a sufficient weather resistance improving effect is likely to be exhibited. Furthermore, volatilization during extrusion and film forming does not easily occur, and a weather resistance enhancing effect is easily exhibited.

Meanwhile, the molecular weight of the end-capping agent means weight average molecular weight.

Carbodiimide-Based End-Capping Agent:

Carbodiimide compounds having a carbodiimide group include monofunctional carbodiimides and polyfunctional carbodiimides. Examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, and di-β-naphthylcarbodiimide. Particularly preferred examples include dicyclohexylcarbodiimide and diisopropylcarbodiimide

Furthermore, as the polyfunctional carbodiimides, carbodiimides having a degree of polymerization of from 3 to 15 are preferably used. Specific examples include 1,5-naphthalenecarbodiimide, 4,4′-diphenylmethanecarbodiimide, 4,4′-diphenyldimethylmethanecarbodiimide, 1,3-phenylenecarbodiimide, 1,4-phenylene diisocyanate, 2,4-tolylenecarbodiimide, 2,6-tolylenecarbodiimide, a mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, and 1,3,5-triisopropylbenzene-2,4-carbodiimide.

Since carbodiimide compounds cause generation of isocyanate-based gas as a result of thermal decomposition, a carbodiimide compound having high heat resistance is preferred. In order to increase heat resistance, if the molecular weight (degree of polymerization) is larger, the carbodiimide compound is more preferable. It is more preferable that the ends of a carbodiimide compound has a structure having high heat resistance. Furthermore, if a carbodiimide compound undergoes thermal decomposition once, the carbodiimide compound is likely to undergo another thermal decomposition. Therefore, a devise, such as adjusting the extrusion temperature of the polyester to be as low as possible, is required.

Regarding the carbodiimide of the end-capping agent, carbodiimides having a cyclic structure (for example, those described in JP-A No. 2011-153209) are also preferable. These compounds exhibit, despite having low molecular weights, an effect equivalent to that of high molecular weight carbodiimides. This is because, a terminal carboxylic acid of a polyester and a cyclic carbodiimide undergo a ring-opening reaction, and one end reacts with this polyester, while the other ring-opened end reacts with another polyester, so that the molecular weight becomes highand thereby suppress generation of an isocyanate-based gas.

Among these compounds having a cyclic structure, in the invention, it is preferable that the end-capping agent be a carbodiimide compound having a carbodiimide group and containing a cyclic structure in which the first nitrogen atom and the second nitrogen atom of the carbodiimide group are bonded by a linking group. Furthermore, it is more preferable that the end-capping agent be a carbodiimide having at least one carbodiimide group that is adjacent to an aromatic ring, and containing a cyclic structure in which the first nitrogen atom and the second nitrogen atom of the carbodiimide group that is adjacent to an aromatic ring are bonded through a linking group (also referred to as an aromatic cyclic carbodiimide).

The aromatic cyclic carbodiimide may have plural cyclic structures.

Regarding the aromatic cyclic carbodiimide, an aromatic carbodiimide which does not have in the molecule a cyclic structure in which the first nitrogen atom and the second nitrogen atom of two or more carbodiimide groups are bonded through a linking group, that is, a monocyclic aromatic carbodiimide can also be preferably used.

The cyclic group has one carbodiimide group (—N═C═N—), and the first nitrogen atom and the second nitrogen atom of the carbodiimide group are bonded through a linking group. One cyclic structure has only one carbodiimide group; however, for example, in the case where the compound has plural cyclic structures in the molecule, such as a spiro ring, it is needless to say that the carbodiimide compound may have plural carbodiimide group as long as each of the cyclic structures that are bonded to spiro atoms has one carbodiimide group. The number of atoms in the cyclic structure is preferably from 8 to 50, more preferably from 10 to 30, even more preferably from 10 to 20, and particularly preferably from 10 to 15.

Here, the number of atoms in the cyclic structure means the number of atoms that directly constitute the cyclic structure. For example, the number of atoms is 8 in an 8-membered ring, and is 50 in a 50-membered ring. If the number of atoms in the cyclic structure is smaller than 8, stability of the cyclic carbodiimide compound is lowered, and storage and use of the compound may become difficult. Furthermore, from the viewpoint of reactivity, there are no particular limitations on the upper limit of the number of ring members, but a cyclic carbodiimide compound having a number of atoms of 50 or less suffers from less difficulty in synthesis, and the production cost is suppressed to a low level. From such a viewpoint, the number of atoms in the cyclic structure is preferably selected in the range of from 10 to 30, more preferably in the range of from 10 to 20, and particularly preferably in the range of from 10 to 15.

Specific examples of the carbodiimide-based end-capping agent having a cyclic structure include the following compounds. However, the invention is not intended to be limited to the following specific examples.

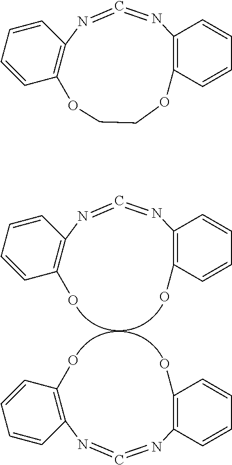 [SMILES: C1=Nc2ccccc2OCCOc2ccccc2N=1 ; Oc1ccccc1N=C=Nc1ccccc1O ; Oc1ccccc1N=C=Nc1ccccc1O]

Epoxy-Based End-Capping Agent:

Preferred examples of the epoxy compound include glycidyl ester compounds and glycidyl ether compounds.

Specific examples of the glycidyl ester compounds include benzoic acid glycidyl ester, t-Bu-benzoic acid glycidyl ester, p-toluic acid glycidyl ester, cyclohexanecarboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linolic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl ester, dodecanedionic acid diglycidyl ester, octadecanedicarboxylic acid diglycidyl ester, trimellitic acid triglycidyl ester, and pyromellitic acid tetraglycidyl ester. These can be used singly or as mixtures of two or more kinds.

Specific examples of the glycidyl ether compounds include phenyl glycidyl ether, 0-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, 2,2-bis[p-(β,γ-epoxypropoxy)phenyl]propane, and bisglycidyl polyethers obtainable by a reaction of bisphenol and epichlorohydrin, such as 2,2-bis(4-hydroxyphenyl)propane or 2,2-bis(4-hydroxyphenyl)methane. These can be used singly or as mixtures of two or more kinds.

Oxazoline-based end-capping agent:

The oxazoline compound is preferably a bisoxazoline compound. Specific examples of the oxazolic compound include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetramethylenebis(4,4-dimethyl-2-oxazoline), 2,2′-9,9′-diphenoxyethanebis(2-oxazoline), 2,2′-cyclohexylenebis(2-oxazoline), and 2,2′-diphenylenebis(2-oxazline). Among these, from the viewpoint of the reactivity with a polyester, 2,2′-bis(2-oxazoline) is most preferably used. Furthermore, the bisoxazoline compounds mentioned above may be used singly, or two or more kinds may be used in combination, as long as the purpose of the invention is achieved.

Such an end-capping agent needs to be kneaded into the polyester film. That is, if the end-capping agent is not allowed to react directly with polyester molecules, the effects described above are not obtained. It is because even if the end-capping agent is added to a coating layer on PET, the polyester does not react with an end-capping agent.

As the polymer base material, a polyester film incorporated with inorganic particles or organic particles may also be used. With this, light reflectance (degree of whiteness) is increased, and the power generation efficiency of solar cells can be increased.

The average particle size of the particles is preferably from 0.1 μm to 10 μm, and more preferably from 0.1 μm to 5 μm, and even more preferred are particles having an average particle size of from 0.15 μm to 1 μm. When the average particle size of the particles is from 0.1 μm to 10 μm, the degree of whiteness of the film can be adjusted to 50 or higher, even if the amount of addition is not increased.

The content of the particles is from 0% to 50% by mass, preferably from 1% to 10% by mass, and even more preferably from 2% to 5% by mass, relative to the total mass of the film. When the amount of addition of the particles is 1% by mass or more, it becomes easier to adjust the degree of whiteness to 50 or higher, and when the amount of addition is 50% by mass or less, an increase in the weight of the film is suppressed, and handling in processing or the like becomes easier. Meanwhile, the terms average particle size and content as used herein refer to, in the case where the film that serves as the base material has a multilayer structure, the average values of the respective layers. That is, the average value is obtained by calculating the value of (particle size or content of each layer)×(thickness of each layer/thickness of all layers) for each layer, and adding all the values into a total sum.

The average particle size of the particles that are contained in the polymer base material in the invention is determined by an electron microscopy method. Specifically, the determination is carried out by the following method.

Particles are observed with a scanning electron microscope, and magnified copies of the photographic thus taken are made by appropriately changing the magnifications according to the size of the particles. Subsequently, for at least 200 or more particles randomly selected, the outer circumference of each particle is traced. The equivalent circle diameters of the particles are measured from these traced images using an image analyzer, and the average value of those diameters is designated as the average particle size.

The particles may be either inorganic particles or organic particles, or the two may be used together. Thus, the light reflectance can be increased thereby, and the power generation efficiency of solar cells can be increased. Examples of inorganic particles that are suitably used include wet and dry silica, colloidal silica, calcium carbonate, aluminum silicate, calcium phosphate, alumina, magnesium carbonate, zinc carbonate, titanium oxide, zinc oxide (zinc white), antimony oxide, cerium oxide, zirconium oxide, tin oxide, lanthanum oxide, magnesium oxide, barium carbonate, zinc carbonate, basic lead carbonate (white lead), barium sulfate, calcium sulfate, lead sulfate, zinc sulfide, mica, titanated mica, talc, clay, kaolin, lithium fluoride, and calcium fluoride, and titanium dioxide and barium sulfate are particularly preferred. In addition, titanium oxide may be any of anatase type or rutile type. Furthermore, the particle surfaces may be subjected to an inorganic treatment with alumina, silica or the like, or may be subjected to an organic treatment with a silicone-based or alcohol-based agent, or the like.

Among these particles, titanium dioxide is preferred, and excellent durability can be provided thereby even under light irradiation. Specifically, when UV is irradiated for 100 hours at 63° C. and 50% Rh at an irradiation intensity of 100 mW/cm², the retention rate of rupture elongation is preferably 35% or higher, and more preferably 40% or higher. As such, since the polymer base material in the invention is prevented from photodecomposition or deterioration even by light irradiation, the polymer base material is more suitable as a back surface protective film of solar cells that are used outdoors.

Titanium dioxide includes rutile type and anatase type, but it is preferable to add titanium dioxide particles containing the rutile type as a main component, to the polymer base material in the invention. While the anatase type has a very large spectral reflectance for ultraviolet radiation, the rutile type has a characteristic of having a large absorptance for ultraviolet radiation (small spectral reflectance). The inventors of the invention paid attention to the difference in such spectral characteristics with regard to the crystal form of titanium dioxide, and could enhance light resistance in a polyester film for solar cell back surface protection (solar cell backsheet) by utilizing the ultraviolet absorption performance of the rutile type. Accordingly, even if other ultraviolet absorbers are not substantially added, excellent film durability under light irradiation is obtained. Therefore, contamination due to bleed-out of ultraviolet absorbers or a decrease in adhesiveness does not easily occur.

In addition, as described above, the titanium dioxide particles related to the invention contains the rutile type as a main component, and the “main component” as used herein means that the amount of rutile type titanium dioxide in the total amount of titanium dioxide particles is greater than 50% by mass.

Furthermore, it is preferable that the amount of anatase type titanium dioxide in the total amount of titanium dioxide particles be 10% by mass or less. The amount of anatase type titanium dioxide is more preferably 5% by mass or less, and particularly preferably 0% by mass. If the content of the anatase type titanium dioxide exceeds the upper limit, the amount of rutile type titanium dioxide in the total amount of titanium dioxide particles is reduced, and therefore, the ultraviolet absorption performance may become insufficient. Also, since the anatase type titanium dioxide has a strong photocatalytic action, light resistance also tends to be decreased by this action. Rutile type titanium dioxide and anatase type titanium dioxide can be distinguished by X-ray structure diffraction or spectral absorption characteristics.

The rutile type titanium dioxide particles in the invention may be subjected to an inorganic treatment with alumina, silica or the like on the particle surface, or may be subjected to an organic treatment with a silicone-based or alcohol-based agent or the like. Rutile type titanium dioxide may be subjected to particle size adjustment and removal of coarse particles, using purification processes, before the titanium dioxide is incorporated into the polyester composition. Regarding the industrial means for purification processes, for example, a jet mill or a ball mill can be applied as a pulverization technique, and for example, dry type or wet type centrifugation can be applied as a classification technique.

In the invention, organic particles can also be used. Organic particles which can withstand heat during the formation of polyester film are preferred, and for example, particles formed from a crosslinkable resin are used. Specifically, polystyrene crosslinked by divinylbenzene, or the like is used. The size and amount of addition of the particles are applied the same as in the case of the inorganic particles.

The addition of particles into the film that serves as the polymer base material is carried out by a method of using known methods, and various methods that are conventionally known can be used. Representative methods thereof include the methods described below.

(A) A method including adding particles before completion of a transesterification reaction or an esterification reaction at the time of polyethylene terephthalate synthesis, or adding particles before the initiation of a polycondensation reaction.

(B) A method including adding particles to polyethylene terephthalate, and melting and kneading the mixture.

(C) A method including producing master pellets (also referred to as a master batch (MB)) in which a large amount of particles have been added in the method of the above item (A) or (B), kneading these with polyethylene terephthalate that does not contain particles, and thereby incorporating a predetermined amount of particles.

(D) A method including directly using the master pellets of the above item (C).

Among these, a master batch method including having a polyester resin and particles mixed in advance using an extruder (MB method: above item (C)) is preferred. Furthermore, a method including feeding a polyester resin that has not been dried in advance and particles to an extruder, and producing an MB while degassing moisture, air or the like, can also be employed. Furthermore, preferably, when an MB is produced using a polyester resin that has been dried in advance even to a small extent, an increase in the acid value of polyester is suppressed. In this case, a method including performing extrusion while removing gases, or a method including performing extrusion without removing gases by using a sufficiently dried polyester resin, may be employed.

For example, in the case of producing an MB, it is preferable to reduce the moisture percentage of the polyester resin to be fed by drying the resin in advance. Regarding the drying conditions, the polyester resin is dried at preferably 100° C. to 200° C., and more preferably 120° C. to 180° C., for one hour or longer, more preferably 3 hours or longer, and even more preferably 6 hours or longer. Thus, the polyester resin is sufficiently dried so that the moisture content of the polyester resin is preferably 50 ppm or less, and more preferably 30 ppm or less. There are no particular limitations on the method for preliminary mixing, and a method using a batch may be used, or a single-screw or twin-screw or higher kneading extruder may also be used. In the case of producing an MB while removing gases, it is preferable to employ a method including melting a polyester resin at a temperature of 250° C. to 300° C., and preferably 270° C. to 280° C., providing one, and preferably two or more, exhaust ports in a preliminary kneading machine, performing continuous suction degassing at a pressure of 0.05 MPa or higher, and more preferably 0.1 MPa or higher to maintaine a reduced pressure inside the mixing machine.

The polymer base material in the invention may contain a large number of fine cavities (voids) in the interior. Thus, a higher degree of whiteness can be suitably obtained thereby. The apparent specific gravity in that case is from 0.7 to 1.3, preferably from 0.9 to 1.3, and more preferably from 1.05 to 1.2. When the apparent specific gravity is 0.7 or more, the polymer base material is imparted with resilience, and processing at the time of the production of a solar cell module can be facilitated. When the apparent specific gravity is 1.3 or less, since the weight of the polymer base material is small, the polymer base material can contribute to weight reduction of solar cells.

The fine cavities described above can be formed by originating from particles and/or a thermoplastic resin that is non-compatible with the polyester that will be described below. Meanwhile, the cavities originating from particles or a thermoplastic resin that is non-compatible with polyester means that cavities exist in the vicinity of the particles or the thermoplastic resin. The cavities can be confirmed by, for example, a cross-sectional photograph of the polymer base material obtained using an electron microscope, or the like.

The resin that is added to the polyester film for cavity formation is preferably a resin that is non-compatible with polyester. Light can be scattered by this resin, and thereby the light reflectance can be increased. Preferred examples of the non-compatible resin that is preferably used include polyolefin resins such as polyethylene, polypropylene, polybutene, and polymethylpentene; polystyrene resins, polyacrylate resins, polycarbonate resins, polyacrylonitrile resins, polyphenylene sulfide resins, polysulfone-based resins, cellulose-based resins, and fluorine-based resins. These non-compatible resins may be homopolymers or may be copolymers, and two or more kinds of non-compatible resins may be used in combination. Among these, polyolefin resins such as polypropylene or polymethylpentene, having small surface tension, or polystyrene-based resins are preferred, and polymethylpentene is most preferred. Since polymethylpentene is relatively greatly different from polyester in terms of surface tension and has a high melting point, polymethylpentene can easily form voids (cavities) having low affinity with polyester in the process for polyester film formation, and is particularly preferable as a non-compatible resin.

When a non-compatible resin is incorporated, the amount is in the range of from 0% to 30% by mass, more preferably in the range of from 1% to 20% by mass, and even more preferably in the range of from 2% to 15% by mass, relative to the total amount of the polyester film. When the content of the non-compatible resin is in the range described above, a high reflectance is obtained, the apparent density of the polymer base material as a whole is not too low, film destruction or the like does not easily occur at the time of stretching, and a decrease in productivity can be prevented.

In the case of adding particles, the average particle size of the particles is preferably from 0.1 μm to 10 μm, more preferably from 0.1 μm to 5 μm, and even more preferably from 0.15 μm to 1 μm. When the average particle size is in this range, a high reflectance (degree of whiteness) is obtained, and a decrease in mechanical strength is suppressed. The content of the particles is from 0% to 50% by mass, preferably from 1% to 10% by mass, and more preferably from 2% by 5% by mass, relative to the total mass of the film. When the content is in the range, a high reflectance (degree of whiteness) is obtained, and a decrease in mechanical strength caused by voids is suppressed. Preferred particles may be particles having low affinity with polyester, and specific examples include particles of barium sulfate.

These white polyester, that is, particle-containing and/or cavity-forming polyester films may be a single layer, or may be a lamination formed from multiple layers of two or more layers. As the lamination, it is preferable to combine a layer having a high degree of whiteness (layer with many voids or particles) and a layer having a low degree of whiteness (layer with fewer voids or particles). The light reflection efficiency can be made high by a layer having many voids or particles, but a decrease in mechanical strength (embrittlement) caused by voids or particles is likely to occur, and in order to compensate this, it is preferable to combine the layer with a layer having a low degree of whiteness. For this reason, a layer having a high degree of whiteness is preferably used as an outer layer, and the layer may be used on one surface or may be used on both surfaces. When a whiter layer using titanium dioxide particles is used as an outer layer, since titanium dioxide particle have UV absorbing ability, the layer also has an effect of enhancing light resistance.

Regarding the layer having a high degree of whiteness, in the case of particle addition, the amount of particles is preferably from 5% by mass to 50% by mass, and more preferably from 6% by mass to 20% by mass. In the case of cavity formation, the apparent specific gravity of the layer having a high degree of whiteness is preferably from 0.7 to 1.2, and more preferably from 0.8 to 1.1. On the other hand, regarding the layer having a low degree of whiteness, in the case of particle addition, the amount of particles is preferably less than 5% by mass and more than or equal to 0% by mass, and more preferably less than or equal to 4% by mass and more than or equal to 1% by mass. In the case of cavity formation, a layer with a low degree of whiteness having an apparent specific gravity of from 0.9 to 1.4 and having a higher density than the whiter layer is preferred, and more preferred is a layer having an apparent specific gravity of from 1.0 to 1.3 and having a higher density than the whiter layer. The less white layer may be a layer which does not contain particles or cavities.

Preferred examples of the layer configuration include whiter layer/less white layer, whiter layer/less white layer/whiter layer, whiter layer/less white layer/whiter layer/less white layer, and whiter layer/less white layer/whiter layer/less white layer/whiter layer.

The thickness ratio of the various layers is not particularly limited, the thickness of each of the layers is preferably from 1% to 99%, and more preferably from 2% to 95%, relative to the thickness of all the layers. If the thickness ratio is more than the upper limit of this range or less than the lower limit, the effects of increasing the reflection efficiency and imparting resistance to light (UV) are not easily obtained. The thickness of all the layers of the polyester film is not particularly limited as long as the thickness is in the range capable of forming a film, the thickness is usually in the range of from 20 μm to 500 μm, and preferably in the range of from 25 μm to 300 μm.

Regarding the method for laminating a polyester film that is used as the polymer base material in the invention, a so-called co-extrusion method using two or three or more melt extrusion machines is preferably used.

In order to increase the degree of whiteness in the invention, using a fluorescent whitening agent such as thiophendiyl is also preferred. A preferred amount of addition is from 0.01% by mass to 1% by mass, more preferably from 0.05% by mass to 0.5% by mass, and even more preferably from 0.1% by mass to 0.3% by mass. When the amount of addition is in this range, it is easier to obtain an effect of increasing the light reflectance, yellowing caused by thermal decomposition at the time of extrusion is suppressed, and a decrease in reflectance is suppressed. As such a fluorescent whitening agent, for example, OB-1 manufactured by Eastman Kodak Co. and the like can be used.

The white polyester film that can be used as the polymer base material in the invention is preferably such that the amount of yellowing change (Δb value) after irradiation of ultraviolet radiation under the conditions of luminance: 100 mW/cm², temperature: 60° C., relative humidity: 50% RH, and irradiation time: 48 hours is less than 5. The Δb value is more preferably less than 4, and even more preferably less than 3. Thus, it is useful from the viewpoint that even if the polyester film is subjected to irradiation of sunlight for a long time, the color change can be reduced. Such an effect is exhibited significantly in the case of a laminate type, particularly when the solar cell module is irradiated through the backsheet side.

—Colored Layer—

The colored layer in the invention is disposed directly on the polymer base material, contains a pigment in an amount of from 2.5 g/m² to 8.5 g/m² and a binder having an acid value of 2 mg KOH/g to 10 mg KOH/g, and has an adhesive force of 50 N/cm or more to an ethylene-vinyl acetate encapsulating material. The colored layer may further include, if necessary, other components such as resins other than those described above, and various additives.

A first function of the colored layer in the invention is a reflective function or a decorative function, and for example, if the colored layer contains a white pigment, the function is to increase the power generation efficiency of a solar cell module by reflecting the portion of incident light that has passed through a photovoltaic cell and reached the backsheet without being used in power generation, and returning the light to the photovoltaic cell. Furthermore, for example, when the colored layer contains a blue or black pigment, decorativeness of the external appearance of a solar cell module when viewed from the side of sunlight incidence (front surface side) is enhanced. Generally, when a solar cell module is viewed from the front surface side (light-receiving side), the backsheet is seen around the photovoltaic cell, and when the backsheet has a colored layer, decorativeness can be enhanced to improve the appearance.

(Pigment)

The colored layer in the invention contains at least one pigment.

Regarding the pigment, for example, a pigment such as titanium oxide, barium sulfate, silicon oxide, aluminum oxide, magnesium oxide, calcium carbonate, kaolin, talc, ultramarine, Prussian blue, or carbon black can be appropriately selected and incorporated. For example, in the case of considering an enhancement of reflectiveness, a white pigment can be used, and in the case of considering designability (decorativeness), a blue pigment or a black pigment can be used.

The colored layer in the invention contains a pigment in an amount in the range of from 2.5 g/m² to 8.5 g/m². If the content of the pigment in the colored layer is less than 2.5 g/m², required coloration is not obtained, and the reflectiveness or decorativeness becomes insufficient. Furthermore, when the content of the pigment in the colored layer is more than 8.5 g/m², the adhesiveness to an EVA sealing material becomes insufficient, and an adhesive force of 50 N/cm or more is not obtained. In addition to that, the surface state of the colored layer is deteriorated, and the film strength decreases.

From these viewpoints, a preferred content of the pigment in the colored layer is in the range of from 3.5 g/m² to 7.5 g/m², and more preferably from 4.5 g/m² to 6.5 g/m².

As the average particle size of the pigment is, the volume average particle size is preferably of from 0.03 μm to 0.8 μm, and more preferably of from about 0.15 μm to 0.5 μm. When the average particle size is in the range described above, high light reflection efficiency is obtained. The average particle size is a value measured by a laser analysis/scattering type particle size distribution analyzer, LA950 [manufactured by Horiba, Ltd.].

(Binder)

The colored layer in the invention contains a binder having an acid value of from 2 mg KOH/g to 10 mg KOH/g. When the acid value of the binder of the colored layer is 2 mg KOH/g or more, the binder can be stably dispersed in water, and when the acid value is 10 mg KOH/g or less, adhesive force to EVA can be exhibited.

Regarding the acid value of the binder that is used in the colored layer, a sample is dissolved in a titrating solvent obtained by mixing xylene and dimethylformamide (1+1), the solution is titrated with a 0.1 mol/L potassium hydroxide-ethanol solution by a potentiometric titration, a deflection point on the titration curve is designated as the end point, and the acid value is determined from the titer obtained until the end point.

When the binder is a binder having an acid value of from 2 mg KOH/g to 10 mg KOH/g, the binder is not easily hydrolyzed as compared with a resin such as polyester having an acid value of more than 10 mg KOH/g, and deterioration over time under high humidity and high temperature is suppressed, so that even in a severe outdoor environment, adhesiveness to an EVA sealing material can be maintained high over a long time. The details of this cause is not clearly known, but it is speculated to be because the main chain of the binder resin is not easily decomposed over time under high humidity and high temperature. It is particularly preferable that the colored layer contain a polyolefin having an acid value of from 2 mg KOH/g to 10 mg KOH/g.

Examples of commercially available polyolefins having an acid value of from 2 mg KOH/g to 10 mg KOH/g include AROBASE SE-1013N manufactured by Unitika Ltd.

The content of the binder in the colored layer is preferably in the range of from 15% to 200% by mass, and more preferably in the range of from 17% to 100% by mass, with respect to the pigment. When the content of the binder is 15% by mass or more, a sufficient strength of the colored layer can be obtained, and when the content is 200% by mass or less, the reflectance or decorativeness can be maintained satisfactorily.

The colored layer in the invention may have another polymer incorporated as a binder, if necessary, in addition to the binder having an acid value of from 2 mg KOH/g to 10 mg KOH/g. Examples include a polyester and a polyurethane, both having an acid value outside the range of from 2 mg KOH/g to 10 mg KOH/g. The amount of addition of the resin having an acid value outside the range of from 2 mg KOH/g to 10 mg KOH/g is 30% by mass or less, and preferably 20% by mass or less, relative to the total amount of the binder. When the proportion of such a resin is 30% by mass or less of the total amount of the binder, a problem such as detachment over time under high humidity and high temperature does not easily occur.

When the colored layer in the invention is formed, in addition to the binder resin and the pigment, additives such as other resins, a crosslinking agent, a surfactant and a filler may be further added as necessary.

(Crosslinking Agent)

The colored layer preferably contains at least one kind of crosslinking agent. Suitable examples of the crosslinking agent for the colored layer include epoxy-based, isocyanate-based, melamine-based, carbodiimide-based, triazine-based, and oxazoline-based crosslinking agents. Among them, from the viewpoint of securing adhesiveness after a lapse of time under high humidity and high temperature, a trazine-based crosslinking agent or an oxazoline-based crosslinking agent is preferred.

Specific examples of the triazine-based crosslinking agent include 2,4-dichloro-6-hydroxy-1,3,5-triazine sodium salt.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis(2-oxazoline), 2,2′-methylenebis(2-oxazoline), 2,2′-ethylenebis(2-oxazoline), 2,2′-trimethylenebis(2-oxazoline), 2,2′-tetramethylenebis(2-oxazoline), 2,2′-hexamethylenebis(2-oxazoline), 2,2′-octamethylenebis(2-oxazoline), 2,2′-ethylenebis(4,4′-dimethyl-2-oxazoline), 2,2′-p-phenylenebis(2-oxazoline), 2,2′-m-phenylenebis(2-oxazoline), 2,2′-m-phenylenebis(4,4′-dimethyl-2-oxazoline), bis(2-oxazolinylcyclohexane) sulfide, and bis(2-oxazolinylnorbornane) sulfide. Furthermore, (co)polymers of these compounds are also preferably used, and particularly, 2-isopropenyl-2-oxazoline is particularly preferred.

Furthermore, as compounds having an oxazoline group, EPOCROS K2010E, EPOCROS K2020E, EPOCROS K2030E, EPOCROS WS-500, EPOCROS WS-700 (all manufactured by Nippon Shokubai Co., Ltd.) and the like can also be utilized.

Specific examples of the carbodiimide-based crosslinking agent include CARBODILITE V-02-L2, CARBODILITE SV-02, CARBODILITE V-02, and CARBODILITE E-01 (all CARBODILITE crosslinking agents, manufactured by Nisshinbo Holdings, Inc.).

In the case of adding a crosslinking agent to the coating liquid for forming a colored layer, the amount of addition of the crosslinking agent (proportion of the structural moiety originating from the crosslinking agent with respect to the binder resin of the colored layer) is preferably from 0.5% to 40% by mass, more preferably from 0.7% to 35% by mass, and particularly preferably from 1.0% to 30% by mass, with respect to the binder resin. When the amount of addition of the crosslinking agent is 0.5% by mass or more, a sufficient crosslinking effect is obtained while maintaining the strength and adhesiveness of the colored layer, and when the amount of addition is 40% by mass or less, the pot life of the coating liquid is maintained long so that an increase in a cost is suppressed. If a coating liquid having a short pot life with an amount of addition of the crosslinking agent of more than 40% by mass is used, aggregates may be generated in the coating layer, and the cost also increases.

(Surfactant)

Examples of the surfactant include known anionic or nonionic surfactants, and the like. When a surfactant is added, the amount of addition thereof is preferably from 0.1 mg/m² to 15 mg/m², and more preferably 0.5 mg/m² to 5 mg/m². When the amount of addition of the surfactant is 0.1 mg/m² or more, the occurrence of cissing is suppressed, and satisfactory layer formation can be achieved. When the amount of addition is 15 mg/m² or less, adhesion can be satisfactorily performed.

(Fine Particles)

The colored layer may also contain inorganic fine particles other than the pigment.

Examples of the inorganic fine particles include particles of silica, calcium carbonate, magnesium oxide, magnesium carbonate, and tin oxide. Among them, from the viewpoint of having a small decrease in adhesiveness when exposed to high humidity and high temperature atmosphere, fine particles of tin oxide and silica are preferred.

The particle size of the inorganic fine particles is, as the volume average particle size, preferably from about 10 nm to 700 nm, and more preferably from about 20 nm to 300 nm. When the particle size is in this range, more satisfactory easy adhesiveness can be obtained. The particle size is a value measured by a laser analysis/scattering type particle size distribution analyzer, LA950 [manufactured by Horiba, Ltd.].

There are no particular limitations on the shape of the inorganic fine particles, and any of a spherical shape, an irregular shape, a needle shape and the like can be used.

The content of the inorganic fine particles is preferably set to the range of from 5% to 400% by mass with respect to the binder resin in the colored layer. When the content of the inorganic fine particles is less than 5% by mass, satisfactory adhesiveness can be easily maintained even when the colored layer is exposed to a hot and humid atmosphere, and when the content is 400% by mass or less, the surface state of the colored layer is not easily deteriorated.

Among them, the content of the inorganic fine particles is preferably in the range of from 50% to 300% by mass.

(Physical Properties)

—Thickness—

There are no particular limitations on the thickness of the colored layer, but the thickness is preferably in the range of from 0.05 μm to 15 μm, and more preferably in the range of from 0.1 μm to 10 μm. When the thickness of the colored layer is 0.05 μm or more, reflectiveness or designability can be suitably obtained, and also, required easy adhesiveness can be suitably obtained. When the thickness is 15 μm or less, a more satisfactory surface state is obtained.

—Adhesive Force—

The colored layer contains a pigment in an amount of from 2.5 g/m² to 8.5 g/m² and a binder having an acid value of 2 mg KOH/g to 10 mg KOH/g. Thereby, when the solar cell element is sealed, an adhesive force of 50 N/cm or more to an ethylene-vinyl acetate sealing material can be acquired. Furthermore, thereby when an sealing material and the colored layer are bonded and stored in an atmosphere at 120° C. and 100% RH for 60 hours, the adhesive force to the sealing material after storage is 60% or more of the adhesive force to the sealing material before storage, and a solar cell backsheet that does not undergo detachment between the polymer base material and the colored layer is obtained.

In addition, the adhesive force may also be increased by subjecting the surface of the backsheet to be bonded to an EVA sealing material (colored layer), to the surface treatment described above, such as a corona treatment or a glow discharge treatment.

Meanwhile, in the invention, the adhesive force of the colored layer to an ethylene-vinyl acetate sealing material is measured as follows.

A sample sheet as an object of measurement is cut to a size of 20 mm in width×150 mm in length to prepare one sheet of a sample specimen. This sample specimen is disposed on a glass plate such that the colored layer is on the inner side, an EVA sheet (EVA sheet manufactured by Mitsui Chemicals Fabro, Inc.: SC50B) that has been cut in advance to a size of 20 mm in width×100 mm in length is interposed therebetween, and the assembly is hot pressed using a vacuum laminator (vacuum laminating machine manufactured by Nisshinbo Holdings, Inc.) to thereby bond the sample specimen to the EVA. The adhesion conditions at this time are as follows.

A vacuum is drawn for 3 minutes at 128° C. using a vacuum laminator, and then pressure is applied for 2 minutes to make provisional bonding. Thereafter, a bonding treatment is applied at 150° C. for 30 minutes using a dry oven. The sample specimen is subjected to bonding such that an area of 20 mm in length from one end of the sample specimen is left unadhered to EVA, while the remaining area of 100 mm in length is bonded to the EVA sheet as described above, and thus a sample for adhesion evaluation is obtained.

The EVA-unadhered area of the sample for adhesion evaluation thus obtained is gripped between upper and lower clip members in a Tensilon (RTC-1210A manufactured by ORIENTEC Co., Ltd.), and a tensile test is carried out at a peeling angle of 180° and a tensile rate of 300 mm/min to measure the adhesive force.

—Reflectance—

When a white pigment is added as a pigment to the colored layer to become the colored layer as a reflective layer, the reflectance to light having a wavelength of 550 nm on the surface where the colored layer is provided is preferably 80% or higher. Meanwhile, the light reflectance is the ratio of the amount of light that is incident from the reflective layer side is reflected on the reflective layer (colored layer), with respect to the amount of incident light.

When the light reflectance is 80% or higher, light that has entered the interior by directly passing through the cell can be effectively returned to the cell, so that the effect of increasing the power generation efficiency is high. By controlling the content of the white pigment in the colored layer to the range of from 2.5 g/m² to 8.5 g/m², the light reflectance can be adjusted to 80% or higher.

When the colored layer is formed as a reflective layer, the thickness of the reflective layer is preferably from 1 μm to 20 μm, and more preferably from about 1.5 μm to 10 μm. When the thickness is 1 μm or more, required decorativeness or reflectance can be obtained, and when the thickness is 20 μm or less, the surface state can be maintained satisfactorily.

(Method for Forming Colored Layer)

The colored layer in the invention can be formed by applying a coating liquid (coating liquid for colored layer formation) for forming a colored layer directly on the polymer base material. For example, in the case where a resin film containing a pigment and the like is pasted using an adhesive such as urethane or polyester, in addition to the overall thickness of the solar cell backsheet becoming thicker, the adhesive is deteriorated by being hydrolyzed due to long-term use, and detachment is likely to occur. Furthermore, for example, in the case of providing a colored layer on the polymer base material by interposing a polymer layer therebetween, detachment may occur at the interface between the polymer layer and the colored layer. On the other hand, if the colored layer is formed directly on the polymer base material by coating, it is convenient, and a uniform thin film can be formed. In addition, detachment does not occur easily.

As the method for application, for example, known coating methods involving a gravure coater or a bar coater can be utilized.

The coating liquid may be a water-based liquid using water as a coating solvent, or may be a solvent-based liquid using an organic solvent such as toluene or methyl ethyl ketone. Among them, from the viewpoint of environmental load, using water as a solvent is preferred. Regarding the coating solvent, one kind may be used alone, or two or more kinds may be used as a mixture.

—Weather Resistant Layer—

The solar cell backsheet of the invention preferably further have a weather resistant layer containing at least one of a fluorine-based resin or a silicone-acrylic composite resin, on the surface of the polymer base material on the side opposite to the surface where the colored layer is disposed.

Examples of the fluorine-based resin that is contained in the coating liquid for weather resistant layer formation include chlorotrifluoroethylene, tetrafluoroethylene, hexafluoropropylene, vinylidene fluoride, trifluoroethylene, a chlorotrifluoroethylene-ethylene copolymer, and a tetrafluoroethylene-perfluoroalkyl vinyl ether copolymer. Among them, from the viewpoints of solubility and weather resistance, a chlorotrifluoroethylene-vinyl ether copolymer obtained by copolymerizing with a vinylic compound is preferred.

The content of the fluorine-based resin relative to the total solid content mass of the coating liquid for weather resistant layer formation is preferably from 40% by mass to 90% by mass, and more preferably from 50% by mass to 80% by mass, from the viewpoints of weather resistance and film strength.

Examples of the silicone-acrylic composite resin that is contained in the coating liquid for weather resistant layer formation include CERANATE WSA1060 and WSA1070 [all manufactured by DIC Corp.]; H7620, H7630 and H7650 [all manufactured by Asahi Kasei Chemicals Corp.].

The content of the silicone-acrylic composite resin relative to the total solid content mass of the coating liquid for weather resistant layer formation is preferably from 40% by mass to 90% by mass, and more preferably from 50% by mass to 80% by mass, from the viewpoints of weather resistance and film strength.

The amount of coating of the coating liquid for weather resistant layer formation is preferably set to from 0.05 g/m² to 30 g/m², and more preferably set to from 1 g/m² to 20 g/m², from the viewpoints of weather resistance and adhesiveness to the polymer base material.

There are no particular limitations on the method for applying the coating liquid for weather resistant layer formation.

Asthe method for application, for example, a gravure coater or a bar coater can be utilized.

As the coating solvent for the coating liquid for weather resistant layer formation, water is preferably used, and it is preferable that 60% by mass or more of the solvent contained in the coating liquid for weather resistant layer formation be water. A water-based coating liquid is preferred from the viewpoint that environmental load is not readily imposed, and when the proportion of water is 60% by mass or more, it is advantageous in view of explosion proofness and safety.

It is desirable, from the viewpoint of environmental load, that the proportion of water in the coating liquid for weather resistant layer formation be larger, and it is more preferable that water be included in an amount of 70% by mass or more relative to the total amount of the solvent.

The weather resistant layer may contain various additives that may be included in a colored layer, such as inorganic fine particles, fine particles other than the inorganic fine particles, an ultraviolet absorber, an oxidation inhibitor, and a surfactant.

The layer thickness of the weather resistant layer is preferably from 0.3 μm to 15.0 μm, and more preferably from 0.5 μm to 12.0 μm. When the film thickness is adjusted to 0.3 μm or more, sufficient weather resistance can be exhibited, and when the film thickness is adjusted to 15.0 μm or less, deterioration of the surface state can be suppressed.

Meanwhile, the weather resistant layer may be a single layer, or may be configured by laminating two or more layers.

At least one layer that is formed directly on the surface of the polymer base material or with another layer interposed therebetween, preferably be contained a surfactant in order to enhance the surface state of the coating film. Examples of the surfactant include nonionic surfactants, anionic surfactants, cationic surfactants, amphoteric surfactants, and fluorine-based surfactants.

There are no particular limitations on the nonionic surfactants that are used in the invention, and conventionally known surfactants can be used. Examples thereof include polyoxyethylene alkyl ethers, polyoxyethylene alkyl phenyl ethers, polyoxyethylene polystyryl phenyl ethers, polyoxyethylene polyoxypropylene alkyl ethers, glycerin fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid esters, polyglycerin fatty acid partial esters, polyoxyethylenated castor oils, polyoxyethylene glycerin fatty acid partial esters, fatty acid diethanolamides, N,N-bis-2-hydroxyalkylamines, polyoxyethylene alkylamines, triethanolamine fatty acid esters, trialkylamine oxides, polyethylene glycols, and copolymers of polyethylene glycol and polypropylene glycol.

There are no particular limitations on the anionic surfactants that are used in the invention, and conventionally known surfactants can be used. Examples thereof include fatty acid salts, abietic acid salts, hydroxyalkanesulfonic acid salts, alkanesulfonic acid salts, dialkylsulfosuccinic acid ester salts, linear alkylbenzenesulfonic acid salts, branched alkylbenzenesulfonic acid salts, alkylnaphthalenesulfonic acid salts, alkylphenoxypolyoxyethylene propylsulfonic acid salts, polyoxyethylene alkyl sulfophenyl ether salts, N-methyl-N-oleyl taurin sodium salt, N-alkylsulfosuccinic acid monoamide disodium salt, petroleum sulfonic acid salts, sulfated beef tallow, sulfuric acid ester salts of fatty acid alkyl esters, alkyl sulfuric acid ester salts, polyoxyethylene alkyl ether sulfuric acid ester salts, fatty acid monogylceride sulfuric acid ester salts, polyoxyethylene alkyl phenyl ether sulfuric acid ester salts, polyoxyethylene styryl phenyl ether sulfuric aid ester salts, alkyl phosphoric acid ester salts, polyoxyethylene alkyl ether phosphoric acid ester salts, polyoxyethylene alkyl phenyl ether phosphoric acid ester salts, partial saponification products of styrene/maleic anhydride copolymers, partial saponification products of olefin/maleic anhydride copolymers, and naphthalenesulfonate formalin condensates.

There are no particular limitations on the cationic surfactants that are used in the invention, and conventionally known surfactants can be used. Examples thereof include alkylamine salts, quaternary ammonium salts, polyoxyethylene alkylamine salts, and polyethylene polyamine derivatives.

The surfactant that is contained in the layers on the polymer base material in the invention is preferably at least one selected from an anionic surfactant, an amphoteric surfactant, or a fluorine-based surfactant.

Meanwhile, it is particularly preferable that both an overcoat layer and a pigment layer contain fluorine-based surfactants.

There are no particular limitations on the amphoteric surfactants that are used in the invention, and conventionally known surfactants can be used. Examples thereof include carboxybetains, aminocarboxylic acids, sulfobetaines, aminosulfuric acid esters, and imidazolines.

Among the surfactants, what is described as “polyoxyethylene” may be interpreted as “polyoxyalkylene” such as polyoxymethylene, polyoxypropylene or polyoxybutylene, and in the invention, these surfactants can also be used.

A more preferred surfactant may be a fluorine-based surfactant containing a perfluoroalkyl group in the molecule. Examples of such a fluorine-based surfactant include anionic type surfactants such as perfluoroalkyl carboxylic acid salts, perfluoroalkyl sulfonic acid salts, perfluoroalkyl phosphoric acid esters; amphoteric type surfactants such as perfluoroalkylbetaines; cationic type surfactants such as perfluoroalkyltrimethylammonium salts; and nonionic type surfactants such as perfluoroalkylamine oxides, perfluoroalkylethylene oxide adducts, oligomers containing perfluoroalkyl groups and hydrophilic groups, oligomers containing perfluoroalkyl groups and oleophilic groups, oligomers containing perfluoroalkyl groups, hydrophilic groups and oleophilic groups, and urethane containing perfluoroalkyl groups and oleophilic groups. Furthermore, the fluorine-based surfactants described in JP-A Nos. S62-170950, S62-226143 and S60-168144 may also be suitably used.

The surfactant is preferably used in an amount in the range of from 0.001% to 10% by mass, and more preferably in the range of from 0.01% to 5% by mass, with respect to the non-volatile component in the layers on the polymer base material in the invention. Furthermore, the surfactant may be used singly, or two or more kinds may be used in combination.

Specific examples of preferred surfactants will be described below, but the invention is not intended to be limited to these.

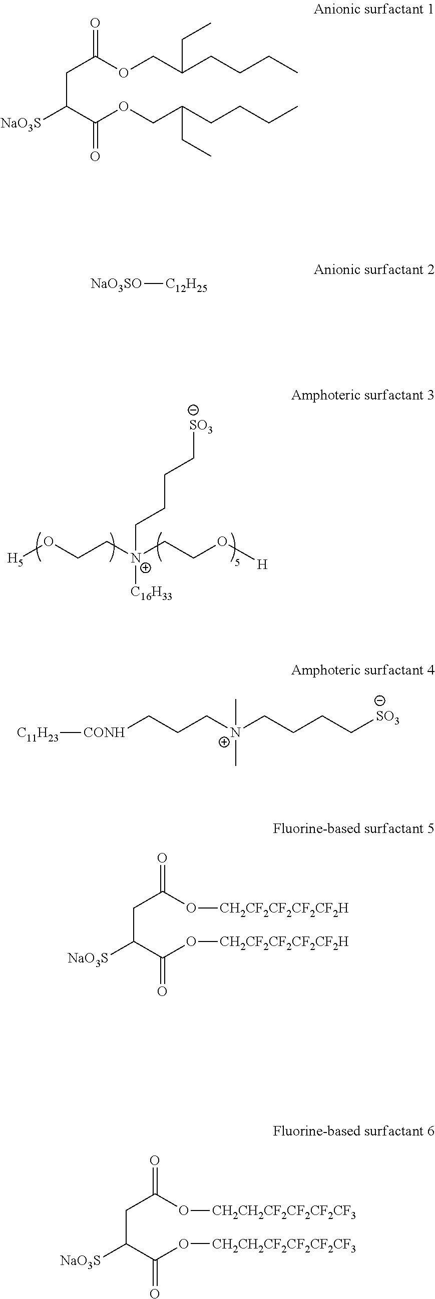

—Production of Backsheet—

The solar cell backsheet of the invention can be suitably produced by forming the colored layer on the polymer base material by coating, as described above.

The coating liquid for colored layer formation is a coating liquid containing a pigment in an amount of from 2.5 g/m² to 8.5 g/m² and a binder having an acid value of from 2 mg KOH/g to 10 mg KOH/g, and the details of the components that constitute the coating liquid or the quantitative range are as described above.

A suitable method for application is also as described above, and for example, a gravure coater or a bar coater can be utilized.

The coating liquid for colored layer formation is preferably a water-based coating liquid in which 60% by mass or more of the solvent contained in this coating liquid is water. A water-based coating liquid is preferable in view of environmental load, and when the proportion of water is 60% by mass or more, it is advantageous in that the environmental load becomes particularly low.

From the viewpoint of environmental load, the proportion of water in the coating liquid for colored layer formation is larger, and it is more preferable that water be included in an amount of 90% by mass or more relative to the total amount of the solvent.

In the coating process in the invention, a colored layer can be formed directly on the polymer base material by applying a coating liquid for colored layer formation directly on the surface of the polymer base material.

<Solar Cell Module>

The solar cell module of the invention is a solar cell module including a solar cell element; an ethylene-vinyl acetate sealing material that seals the solar cell element; a surface protective member that is bonded with the sealing material and protects the light-receiving surface side; and the solar cell backsheet of the invention, in which a colored layer is directly bonded with the encapsulating material, and the solar cell module has a back surface protective member that protects the opposite side of the light-receiving surface. The solar cell module is configured such that a solar cell element that converts the light energy of sunlight to electrical energy is disposed between a transparent substrate (front surface protective member) through which sunlight enters, and the solar cell backsheet of the invention described above, and the space between the substrate and the backsheet is sealed with an ethylene-vinyl acetate (EVA) sealing material.

Regarding the members other than the solar cell module, photovoltaic cell and backsheet, the details are described in, for example, “Taiyoko Hatsuden Shisutemu Kosei Zairyo [Solar power generation system constituting materials]” (reviewed by Eiichi Sugimoto, Kogyo Chosakai Publishing Co., Ltd., published in 2008).

Any transparent substrate having light transmissibility of being capable of transmitting sunlight is acceptable, and the transparent substrate can be appropriately selected from base materials that transmit light. From the viewpoint of the power generation efficiency, it is more preferable that light transmittance be higher, and examples of such a substrate that can be suitably used include a glass substrate, and transparent resins such as an acrylic resin.

As the solar cell element, various known solar cell elements, including silicon-based elements such as single crystal silicon, polycrystalline silicon, and amorphous silicon; and Group III-V or Group II-VI compound semiconductor-based elements such as copper-indium-gallium-selenium, copper-indium-selenium, cadmium-tellurium, and gallium-arsenic can be applied.

### EXAMPLES

Hereinafter, the invention will be more specifically described by way of Examples, but the invention is not intended to be limited to the following Examples as long as the gist is maintained. Meanwhile, unless particularly stated otherwise, the unit “parts” is on a mass basis.

### Example 1

### Production of Polymer Base Material

<Synthesis of Polyester>

A slurry of 100 kg of high purity terephthalic acid (manufactured by Mitsui Chemicals, Inc.) and 45 kg of ethylene glycol (manufactured by Nippon Shokubai Co., Ltd.) was sequentially supplied over 4 hours into an esterification reaction tank that had been fed in advance with about 123 kg of bis(hydroxyethyl) terephthalate and maintained at a temperature of 250° C. and a pressure of 1.2×105 Pa, and after completion of the supply, the esterification reaction was carried out for another hour. Thereafter, 123 kg of the esterification reaction product thus obtained was transferred to a polycondensation reaction tank.

Subsequently, ethylene glycol was added to the polycondensation reaction tank to which the esterification reaction product had been transferred, in an amount of 0.3% by mass with respect to the polymer thus obtainable. After the mixture was stirred for 5 minutes, an ethylene glycol solution of cobalt acetate and manganese acetate was added thereto in amounts of 30 ppm and 15 ppm, respectively, with respect to the polymer thus obtainable. The mixture was further stirred for 5 minutes, and then a 2 mass % ethylene glycol solution of a titanium alkoxide compound was added thereto in an amount of 5 ppm with respect to the polymer thus obtainable. For the titanium alkoxide compound, the titanium alkoxide compound (Ti content=4.44% by mass) synthesized in Example 1 of paragraph [0083] of JP-A No. 2005-340616 was used. After 5 minutes therefrom, a 10 mass % ethylene glycol solution of ethyl diethylphosphonoacetate was added thereto in an amount of 5 ppm with respect to the polymer thus obtainable, and thus a low polymer was obtained.

Thereafter, while the low polymer was stirred at 30 rpm, the reaction system was slowly heated from 250° C. to 285° C., and simultaneously, the pressure was decreased to 40 Pa. The time to reach the final temperature and the final pressure was adjusted to 60 minutes in total. The reaction was kept for 3 hours, and then, the reaction system was purged with nitrogen and returned to normal pressure to thereby terminate the polycondensation reaction. Then, the molten polymer thus obtained was discharged into cold water in a strand form and immediately cut. Thus, pellets (diameter about 3 mm, length about 7 mm) of the polymer were produced.

<Solid Phase Polymerization>

The pellets obtained as described above were maintained in a vacuum container kept at 40 Pa at a temperature of 220° C. for 30 hours, and thus solid phase polymerization was carried out.

<Base Formation>

The pellets obtained after performing solid phase polymerization as described above were molten at 280° C. and cast on a metal drum, and thus an unstretched base having a thickness of about 2.5 mm was produced. Thereafter, the unstretched base was stretched 3 times in the longitudinal direction at 90° C., and was further stretched 3.3 times in the transverse direction at 120° C. Thereafter, the stretched base was thermally fixed for one minute at 215° C., and thus a biaxially stretched polyethylene terephthalate base material (hereinafter, may be referred to as “PET base material”) having a thickness of 250 μm was obtained.

The processes were carried out in the similar manner except that the conditions for solid phase polymerization were changed, and thus, PET base materials having carboxyl group contents (AV) of 16 equivalents/ton, 18 equivalents/ton, and 22 equivalents/ton, respectively, were obtained.

(AV)

0.1 g of a polyester sample was dissolved in 10 ml of benzyl alcohol, and then chloroform was added thereto to obtain a mixed solution. A Phenol Red indicator was added dropwise to the mixed solution. The solution was titrated with a standard liquid (0.01 N KOH-benzyl alcohol mixed solution), and the terminal carboxyl group amount was determined from the amount of dropwise addition.

<Colored Layer>

—Preparation of Titanium Dioxide Dispersion—

The components in the composition described below were mixed, and the mixture was subjected to a dispersion treatment for one hour using a Dyno Mill type dispersing machine.

(Composition of Titanium Dioxide Dispersion)

| | |
|---|---|
| Titanium dioxide (white pigment, volume | 45.6 mass % |
| average particle size: 0.3 μm) [TIPAQUE | |
| CR95, manufactured by Ishihara Sangyo | |
| Kaisha, Ltd., solid content: 100%] | |
| Polyvinyl alcohol | 22.8 mass % |
| [PVA-105, manufactured by Kuraray Co., Ltd., | |
| solid content: 10%] | |
| Surfactant | 5.5 mass % |
| [DEMOL EP, manufactured by Kao Corp., | |
| solid content: 25%] | |
| Distilled water | added to make up 100% |

—Preparation of Coating Liquid for Colored Layer Formation—

The components in the composition described below were mixed, and thus a coating liquid for colored layer formation was prepared.

(Composition of Coating Liquid)

| | |
|---|---|
| Titanium dioxide dispersion | 31.0 mass % |
| Polyolefin | 54.2 mass % |
| [AROBASE SE-1013N, manufactured by Unitika Ltd., | |
| acid value: 2 mg KOH/g, | |
| solid content: 20% by mass] | |
| Polyoxyalkylene alkyl ether | 2.5 mass % |
| [NAROACTY CL95, manufactured by Sanyo Chemical | |
| Industries, Ltd., solid content: 1% by mass] | |
| Oxazoline compound | 2.8 mass % |
| [EPOCROS WS-700, manufactured by Nippon Shokubai | |
| Co., Ltd., solid content: 25%; crosslinking agent] | |
| Distilled water | 1.2 mass % |

(Method for Measuring Acid Value)

Regarding the acid value of the binder used in the colored layer, a sample was dissolved in a titrating solvent obtained by mixing xylene and dimethylformamide (1+1), the solution was titrated with a 0.1 mol/L potassium hydroxide-ethanol solution by a potential difference titration method, a deflection point on the titration curve was designated as the end point, and the acid value was determined from the titer obtained until the end point.

—Formation of Colored Layer—

The coating liquid thus obtained was applied on one surface on the biaxially stretched PET base material, and dried for one minute at 180° C. Thus, a colored layer (white layer) having a thickness of 5 μm, a titanium dioxide amount of 5.5 g/m², and a binder amount of 4.2 g/m² was formed.

<Back Surface Undercoat Layer>

—Preparation of Pigment Dispersion—

The various components in the composition described below were mixed, and the mixture was subjected to a dispersion treatment for one hour using a Dyno Mill type dispersing machine.

(Composition of Pigment Dispersion)

| | |
|---|---|
| Titanium dioxide (white pigment, volume | 45.6 mass % |
| average particle size: 0.3 μm) | |
| [TIPAQUE CR95, manufactured by Ishihara | |
| Sangyo Kaisha, Ltd., solid content] 100%] | |
| Polyvinyl alcohol | 22.8 mass % |
| [PVA-105, manufactured by Kuraray Co., Ltd., | |
| solid content 10%] | |
| Surfactant | 5.5 mass % |
| [DEMOL EP, manufactured by Kao Corp., | |
| solid content 25%] | |
| Distilled water | added to make up 100% |

—Preparation of Coating Liquid for Back Surface Undercoat Layer Formation—

The components in the composition described below were mixed, and thus a coating liquid for undercoat layer formation was prepared.

(Composition of Coating Liquid)

| | |
|---|---|
| Aqueous dispersion of silicone polymer | 36.4 parts by mass |
| (CERANATE WSA1070, | |
| manufactured by DIC Corp., | |
| solid content concentration: 37.4% by mass) | |
| Oxazoline-based crosslinking agent | 11.2 parts by mass |
| (EPOCROS WS-700, manufactured by Nippon | |
| Shokubai Co., Ltd. (solid content: 25% by mass); | |
| crosslinking agent having an oxazoline group) | |
| Diammonium hydrogen phosphate | 0.4 parts by mass |
| (onium compound) | |
| Pigment dispersion | 49.4 parts by mass |
| Distilled water | 1.1 parts by mass |

—Formation of Back Surface Undercoat Layer—

The coating liquid for undercoat layer formation thus obtained was applied on the surface of the PET base material opposite to the surface where the white layer had been formed, such that the amount of binder would be 6.1 g/m² as an amount of coating, and the coating liquid was dried for one minute at 180° C. Thus, an undercoat layer having a dried thickness of about 8 μm was formed.

<Back Surface Weather Resistant Layer>

—Preparation of Coating Liquid for Back Surface Weather Resistant Layer Formation—

The components in the composition described below were mixed, and thus a coating liquid for back surface weather resistant layer formation was prepared.

(Composition of Coating Liquid)

| | |
|---|---|
| Aqueous dispersion of fluoropolymer | 20.7 mass % |
| (OBBLIGATO AW0011F, AGC Coat-Tech Co., Ltd., | |
| solid content concentration 36.1% by mass) | |
| Polyoxyalkylene alkyl ether | 0.4 mass % |
| (NAROACTY CL-95, manufactured by Sanyo | |
| Chemical Industries, Ltd., solid content 1%) | |
| Oxazoline-based crosslinking agent | 6.0 mass % |
| (EPOCROS WS-700, manufactured by Nippon | |
| Shokubai Co., Ltd. (solid content: 25% by mass); | |
| crosslinking agent having an oxazoline group) | |
| Silica sol | 0.2 mass % |
| [SNOWTEX UP, manufactured by Nissan Chemical | |
| Industries, Ltd., solid content 20%] | |
| Silane coupling agent | 4.7 mass % |
| [TSL8340, manufactured by Momentive | |
| Performance Materials, Inc., solid content 1%] | |
| Polyolefin wax dispersion | 12.5 mass % |
| [CHEMIPEARL W950, manufactured by | |
| Mitsui Chemicals, Inc., solid content 5%] | |
| Distilled water | added to make |
| | up 100% |

—Formation of Back Surface Weather Resistant Layer—

The coating liquid for back surface weather resistant layer formation thus obtained was applied on the back surface undercoat layer such that the amount of binder would be 1.3 g/m² as an amount of coating, and the coating liquid was dried for one minute at 180° C. Thus, a back surface weather resistant layer having a dried thickness of about 1.3 μm was formed.

In this manner, a backsheet sample having respective layers formed by coating on both surfaces of a PET base material was produced. The following evaluations were carried out on the sample. The results are presented in Table 1.

<Evaluation>

—1. Adhesiveness—

[A] Adhesiveness Before Lapse of Time Under High Humidity and High Temperature (Fr)

The sample sheet produced as described above was cut to a size of 20 mm in width×150 mm in length, and one sheet of a sample specimen was prepared. The sample specimen was disposed on a glass plate such that the white layer was on the inner side, an EVA sheet (EVA sheet manufactured by Mitsui Chemicals Fabro, Inc.: SC50B) that had been cut in advance to a size of 20 mm in width×100 mm in length was interposed therebetween, and the assembly was hot pressed using a vacuum laminator (vacuum laminating machine manufactured by Nisshinbo Holdings, Inc.) to thereby bond the sample specimen to the EVA. The bonding conditions at the time were as follows.

A vacuum was drawn for 3 minutes at 128° C. using a vacuum laminator, and then pressure was applied for 2 minutes to perform provisional adhesion. Thereafter, a bonding treatment was applied at 150° C. for 30 minutes using a dry oven. The sample specimen bonded in this manner was subjected to bonding as described above such that an area of 20 mm in length from one end of the sample specimen was left unadhered to EVA, while the remaining area having 100 mm in length was bonded to the EVA sheet, and thus a sample for adhesion evaluation was obtained.

The EVA-unadhered area of the sample for adhesion evaluation thus obtained was gripped between upper and lower clip members in a Tensilon (RTC-1210A manufactured by ORIENTEC Co., Ltd.), and a tensile test was carried out at a peeling angle of 180° and a tensile rate of 300 mm/min to measure the adhesive force.

The adhesive force between the EVA and the white layer thus measured was evaluated, and detachment occurred at the interface between the white layer and the base material was also evaluated and was ranked according to the following evaluation criteria.

<Evaluation Criteria: Interfacial Detachment>

A: Adhesion was very satisfactory (rate of the occurrence of interfacial detachment: less than 10%)

B: Adhesion was satisfactory (rate of the occurrence of interfacial detachment: more than or equal to 10% and less than 70%)

C: Adhesion was poor (rate of the occurrence of interfacial detachment: 70% or more)

[B] Adhesiveness after Lapse of Time Under High Humidity and High Temperature (PCT)

The sample for adhesion evaluation thus obtained was maintained for 48 hours under the environmental conditions of 120° C. and 100% RH (a lapse of time under high humidity and high temperature), and then the adhesive force was measured by the same method as in section [A]. In regard to the adhesive force after maintenance thus measured, the ratio of the same sample for adhesion evaluation with respect to the [A] adhesive force before a lapse of time under high humidity and high temperature [%=adhesive force after a lapse of time under high humidity and high temperature/[A] adhesive force before a lapse of time under high humidity and high temperature×100] was calculated. Furthermore, the adhesive force was evaluated by the same method as in section [A], based on the measured adhesive force after a lapse of time under high humidity and high temperature.

—2. Resistance to Hydrolysis—

The sample sheet produced as described above was cut to a size of 20 mm in width×150 mm in length, and two sheets of sample specimens were prepared. For these sample specimens, one sheet was evaluated as is (abbreviated to Fr), while one sheet was evaluated after keeping for 60 hours under the environmental conditions of 120° C. and 100% RH (after a lapse of time under high humidity and high temperature, abbreviated to PCT60h). Each sample specimen was gripped between upper and lower clip members in a Tensilon (RTC-1210A manufactured by ORIENTEC Co., Ltd.), and was subjected to a tensile test at a tensile rate of 300 mm/min to measure the rapture elongation. The ratio of rupture elongation after PCT60h/rupture elongation of Fr was determined, and the sample specimens were ranked according to the following evaluation criteria.

A: Resistance to hydrolysis was very satisfactory (80% or more)

B: Resistance to hydrolysis was satisfactory (more than or equal to 60% and less than 80%)

C: Resistance to hydrolysis was not sufficient (more than or equal to 40% and less than 60%)

D: Resistance to hydrolysis was slightly insufficient (more than or equal to 20% and less than 40%)

E: Resistance to hydrolysis was insufficient (less than 20%)

—3. Measurement of Reflectance—

For the solar cell backsheet thus obtained, reflectance was measured by the measurement method described below.

A φ60 integrating sphere 130-0632 (Hitachi, Ltd.) and a 10° inclined spacer were attached to a spectrophotometer (manufactured by Hitachi, Ltd.; U-3410 Spectrophotometer) to measure the reflectance of the backsheet. Meanwhile, the backsheet used as a sample was set up such that the longitudinal direction was laid in the vertical direction, the band parameter was set to 2/servo, the gain was set to 3, and the reflectance was measured over the range of 187 nm to 2600 nm at a detection rate of 120 nm/min. Furthermore, in order to standardize the reflectance, Al2O3 accessory to the spectrophotometer was used as a standard reflector. Meanwhile, the reflectance was calculated as a reflectance at a wavelength of 550 nm. Measurement was carried out for the surface on the side where the colored layer existed. The results are presented in Table 1.

—4. Cissing—

For the solar cell backsheet thus obtained, the coated surface state was visually inspected using transmitted light, and the presence or absence of cissing with a size of 0.5 mm or more was checked. The examination results were ranked according to the following evaluation criteria.

A: Zero (0)/A4 size

B: From 1 to 5/A4 size

### Examples 2 to 4

Solar cell backsheets were produced in the similar manner as in Example 1 using the PET base material as that used in Example 1, except that the crosslinking agent of the colored layer was changed as indicated in Table 1, and evaluations were carried out. Meanwhile, as the triazine-based crosslinking agent, 2,4-dichloro-6-hydroxy-1,3,5-triazine sodium salt was used.

### Example 5

A solar cell backsheet was produced in the similar manner as in Example 2, except that a PET base material having an AV value of 18 equivalents/ton was used as the PET base material, and evaluations were carried out.

### Comparative Example 1

A solar cell backsheet was produced in the similar manner as in Example 1, except that no crosslinking agent was used in the colored layer and the content of the pigment was increased, and evaluations were carried out.

### Comparative Example 2

A solar cell backsheet was produced in the similar manner as in Example 1, except that no crosslinking agent was used in the colored layer, and evaluations were carried out.

### Comparative Example 3

A solar cell backsheet was produced in the similar manner as in Example 2, except that a carbodiimide-based crosslinking agent (CARBODILITE V-02-L2, manufactured by Nisshinbo Holdings, Inc.) was used as a crosslinking agent in the colored layer, and evaluations were carried out.

### Example 6

A solar cell backsheet was produced in the similar manner as in Example 2, except that a PET base material manufactured by Fujifilm Corp. (AV value: 22 equivalents/ton) was used as the PET base material, and evaluations were carried out.

### Comparative Example 4

A solar cell backsheet was produced in the similar manner as in Example 2, except that HITECH S-3148 (manufactured by Toho Chemical Industry Co., Ltd.) (acid value: 25 mg KOH/g) was used as a binder of the colored layer, and evaluations were carried out.

### Comparative Example 5

### Undercoat Layer

—Preparation of Coating Liquid for Undercoat Layer Formation—

The components in the composition described below were mixed, and thus a coating liquid for undercoat layer formation was prepared.

(Composition of Coating Liquid)

| | |
|---|---|
| Acrylic binder | 2.6 parts by mass |
| (AS-563A manufactured by Daicel FineChem, | |
| Ltd., solid content: 28% by mass) | |
| Olefin-based binder | 3.6 parts by mass |
| (AROBASE SE-1013N, manufactured by Unitika | |
| Ltd., solid content: 20% by mass) | |
| Carbodiimide compound (crosslinking agent) | 1.7 parts by mass |
| (CARBODILITE V-02-L2, manufactured by | |
| Nisshinbo Holdings, Inc., solid content: | |
| 10% by mass) | |
| Oxazoline compound (crosslinking agent) | 0.3 parts by mass |
| (EPOCROS WS700, manufactured by Nippon | |
| Shokubai Co., Ltd., solid content: 25% by mass) | |
| Surfactant | 1.5 parts by mass |
| (NAROACTY CL95, manufactured by Sanyo | |
| Chemical Industry Co., Ltd., solid | |
| content: 1% by mass) | |
| Distilled water | 89.4 parts by mass |

—Formation of Undercoat Layer—

The coating liquid for undercoat layer formation thus obtained was applied on one surface of a PET base material, which was the same as that used in Example 1, such that the amount of binder would be 0.1 g/m² as an amount of coating, and the coating liquid was dried at 180° C. for one minute. Thus, an undercoat layer having a dried thickness of about 0.1 μm was formed.

<Colored Layer>

A colored layer was formed on the undercoat layer. The colored layer was formed in the similar manner as in Example 1, except that no crosslinking agent was used. A solar cell backsheet was produced thereby, and evaluations were carried out.

### Comparative Example 6

A solar cell backsheet was produced by forming an undercoat layer in the same manner as in Comparative Example 5, and then forming a colored layer on the undercoat layer in the same manner as in Example 2, and evaluations were carried out.

### Example 7

A backsheet was produced in the similar manner as in Example 2, except that the binder in the colored layer was changed to (manufactured by Unitika Ltd., trade name: a product with two-fold acid component, acid value: 5 mg KOH/g), and evaluations were carried out.

### Example 8

A backsheet was produced in the similar manner as in Example 2, except that the binder in the colored layer was changed to (manufactured by Unitika Ltd., trade name: a product with six-fold acid component, acid value: 10 mg KOH/g), and evaluations were carried out.

### Example 9

A backsheet of Example 9 was produced in the similar manner as in Example 2, except that the synthesis of polyethylene terephthalate and the method for producing the polymer base material were carried out by the methods described below.

<Synthesis of Polyethylene Terephthalate>

100 parts by mass of dimethyl terephthalate, 61 parts by mass of ethylene glycol, and 0.06 parts by mass of magnesium acetate tetrahydrate salt were introduced into a transesterification reaction container, and the mixture was heated to 150° C. to melt and was stirred. While the temperature inside the reaction container was slowly increased to 235° C., a reaction was carried out, and methanol thus produced was distilled out to the outside of the reaction container. After distillation of methanol was completed, 0.02 parts by mass of trimethylphosphoric acid was added thereto. After trimethylphosphoric acid was added, 0.03 parts by mass of antimony trioxide was added thereto, and the reactants were transferred to a polymerization apparatus. Subsequently, the temperature inside the polymerization apparatus was increased from 235° C. to 290° C. over 90 minutes, and during the same time, the pressure inside the apparatus was reduced from atmospheric pressure to 100 Pa over 90 minutes. After the stirring torque of the content in the polymerization apparatus reached a predetermined value, the inside of the apparatus was returned to atmospheric pressure with nitrogen gas, and polymerization was terminated.

The interior of the polymerization apparatus was pressurized with nitrogen gas by opening a valve in the lower part of the polymerization apparatus, and polyethylene terephthalate (PET) in a state of completed polymerization was discharged into water in a strand form. Strands were cut into chips using a cutter. In this manner, a PET having an intrinsic viscosity IV of 0.58 and an acid value (AV) of 12 was obtained. This was designated as PET-A.

<Solid Phase Polymerization of Polyester>

PET-A was preliminarily dried for 3 hours at from 150° C. to 160° C., and then solid phase polymerization was carried out for 25 hours at 100 Torr (13332 Pa) and 205° C. in a nitrogen gas atmosphere. Thus, PET-B was obtained.

<Production of Master Pellets Containing Polyester and End-Capping Agent>

90 parts by mass of PET-B and 10 parts by mass of the following compound as an end-capping agent were blended, and a mixture thus obtained was supplied to a twin-screw kneading machine and was melt and kneaded at 280° C. The resultant was discharged into water in a strand form, and strands were cut into chips using a cutter. This was designated as PET-C.

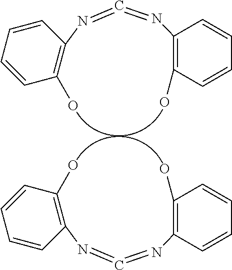 [SMILES: Oc1ccccc1N=C=Nc1ccccc1O ; Oc1ccccc1N=C=Nc1ccccc1O]

<Formation of Polyester Film>

PET-B and PET-C were dried at 180° C. for 3 hours, subsequently an end-capping agent was incorporated such that the content of the end-capping agent would be the amount indicated in Table 1, and the mixture was fed to an extruder and kneaded at 280° C. The kneaded product was passed through a gear pump and a filtering machine, subsequently extruded through a T-die onto an electrostatically charged cooling drum at 25° C., and solidified by cooling. Thus, an unstretched sheet was obtained. The unstretched polymer base material was subjected to biaxial stretching by stretching 3.4 times in the longitudinal direction at 90° C., and further stretching 4.5 times in the transverse direction at 120° C. The stretched polymer base material was thermally fixed for 30 seconds at 200° C., and then was thermally relaxed for 10 seconds at 190° C. Thus, a polymer base material which was a polyethylene terephthalate film (PET film) having a thickness of 240 μm was produced.

A backsheet of Example 9 was produced by the same similar as that used in Example 2, using this polymer base material.

### Example 10

In relation to Example 1, a 50 mass % fraction of the polyethylene terephthalate resin relative to the total mass of the resin was dried in advance at 120° C. for about 8 hours at 10-3 Ton (0.1333 Pa). A backsheet of Example 10 was produced by the similar method as that used in Example 2, except that the fraction was mixed with the same mass of rutile type titanium dioxide having an average particle size of 0.3 μm based on the measurement method according to the electron microscopic method described above, a mixture thus obtained was supplied to a vent-type twin-screw extruder and extruded at 275° C. while the mixture was kneaded and degassed, and thus particle (titanium oxide)-containing pellets were prepared.

### Example 11

A backsheet of Example 11 was produced by the similar method as that used in Example 2, except that the surface treatment of the PET film was carried out by a glow discharge treatment that will be described below in Example 2.

<Glow Discharge Treatment>

A polyethylene terephthalate film was heated to 145° C. using a heating roller, and then was subjected to a glow discharge treatment under the conditions of a treatment atmosphere pressure of 0.2 Torr, a discharge frequency of 30 kHz, a power output of 5000 w, and a discharge treatment intensity of 4.2 kV·A·min/m².

### Example 12

A backsheet of Example 12 was produced by the similar method as in Example 2, except that a fluorine-based surfactant, sodium 1,2-{bis(3,3,4,4,5,5,6,6-nanofluorohexylcarbonyl)}ethane sulfonate (manufactured by Fujifilm Fine Chemicals Co., Ltd., solid content 1.0%) was added in an amount of 3.0% by mass.

### Example 13

A backsheet of Example 13 was produced by the similar method as that used in Example 1, except that the content of the pigment in the colored layer was changed as indicated in Table 1.

### Example 14

A backsheet of Example 14 was produced by the similar method as that used in Example 1, except that the content of the pigment in the colored layer was changed as indicated in Table 1.

<Production of Solar Cell Module>

A reinforced glass plate having a thickness of 3.2 mm, an EVA sheet [SC50B manufactured by Mitsui Chemicals Fabro, Inc.], a crystalline photovoltaic cell, an EVA sheet [SC50B manufactured by Mitsui Chemicals Fabro, Inc.], and the solar cell backsheet 1 of Example 1 were superimposed in this order and hot pressed using a vacuum laminator [manufactured by Nisshinbo Holdings, Inc., vacuum laminator] to be bond the members with EVA. The backsheet was disposed such that its colored layer would be in contact with the EVA sheet. Furthermore, the conditions for bonding EVA were as follows.

A vacuum was drawn for 3 minutes at 128° C. using a vacuum laminator, and then pressure was applied for 2 minutes to perform provisional bonding. Thereafter, a bonding treatment was applied at 150° C. for 30 minutes using a dry oven.

In this manner, a crystalline solar cell module 1 was produced.

Furthermore, crystalline solar cell modules 2 to 5 were produced by using the solar cell backsheets 2 to 5 of Examples 2 to 5 instead of the solar cell backsheet 1.

The solar cell modules 1 to 5 thus produced were subjected to power generation operation, and all of them exhibited satisfactory power generation performance as solar cells.

TABLE 1

| | | | | | Colored layer | | | | | |
|---|---|---|---|---|---|---|---|---|---|---|
| | Polymer base material | | Undercoat layer | | | | Binder | | Pigment | |
| | | AV value, | Presence or | | Crosslinking agent | | | Acid value | | mass % |
| | Kind | equivalents/t | absence | Binder | Kind | mass % | Kind | mgKOH/g | Kind | (g/m²) |
| Example 1 | PET | 16 | Absent | — | Oxazoline | 6.4% | Polyolefin | 2 | CR95 | 49.8% |
| | | | | | | | (SE1013N) | | | (5.5 g/m²) |
| Example 2 | PET | 16 | Absent | — | Oxazoline | 12.7% | Polyolefin | 2 | CR95 | 49.8% |
| | | | | | | | (SE1013N) | | | (5.5 g/m²) |
| Example 3 | PET | 16 | Absent | — | Oxazoline | 25.4% | Polyolefin | 2 | CR95 | 49.8% |
| | | | | | | | (SE1013N) | | | (5.5 g/m²) |
| Example 4 | PET | 16 | Absent | — | Triazine | 2.0% | Polyolefin | 2 | CR95 | 49.8% |
| | | | | | | | (SE1013N) | | | (5.5 g/m²) |
| Example 5 | PET | 18 | Absent | — | Oxazoline | 12.7% | Polyolefin | 2 | CR95 | 49.8% |
| | | | | | | | (SE1013N) | | | (5.5 g/m²) |
| Comparative | PET | 16 | Absent | — | Absent | Absent | Polyolefin | 2 | CR95 | 62.0% |
| Example 1 | | | | | | | (SE1013N) | | | (9.0 g/m²) |
| Comparative | PET | 16 | Absent | — | Absent | Absent | Polyolefin | 2 | CR95 | 49.8% |
| Example 2 | | | | | | | (SE1013N) | | | (5.5 g/m²) |
| Comparative | PET | 16 | Absent | — | Carbodiimide | 12.7% | Polyolefin | 2 | CR95 | 49.8% |
| Example 3 | | | | | | | (SE1013N) | | | (5.5 g/m²) |
| Example 6 | PET | 22 | Absent | — | Oxazoline | 12.7% | Polyolefin | 2 | CR95 | 49.8% |
| | | | | | | | (SE1013N) | | | (5.5 g/m²) |
| Comparative | PET | 16 | Absent | — | Oxazoline | 12.7% | Polyolefin | 25 | CR95 | 49.8% |
| Example 4 | | | | | | | (S3148) | | | (5.5 g/m²) |
| Comparative | PET | 16 | Present | Acrylic/ | Absent | Absent | Polyolefin | 2 | CR95 | 49.8% |
| Example 5 | | | | olefin | | | (SE1013N) | | | (5.5 g/m²) |
| Comparative | PET | 16 | Present | Acrylic/ | Oxazoline | 12.7% | Polyolefin | 2 | CR95 | 49.8% |
| Example 6 | | | | olefin | | | (SE1013N) | | | (5.5 g/m²) |
| Example 7 | PET | 16 | Absent | — | Oxazoline | 12.7% | Polyolefin | 5 | CR95 | 49.8% |
| | | | | | | | (SE1013N) | | | (5.5 g/m²) |
| Example 8 | PET | 16 | Absent | — | Oxazoline | 12.7% | Polyolefin | 10 | CR95 | 49.8% |
| | | | | | | | (SE1013N) | | | (5.5 g/m²) |
| Example 9 | End-capped | 12 | Absent | — | Oxazoline | 12.7% | Polyolefin | 2 | CR95 | 49.8% |
| | PET | | | | | | (SE1013N) | | | (5.5 g/m²) |
| Example 10 | White PET | 16 | Absent | — | Oxazoline | 12.7% | Polyolefin | 2 | CR95 | 49.8% |
| | | | | | | | (SE1013N) | | | (5.5 g/m²) |
| Example 11 | Glow-treated | 16 | Absent | — | Oxazoline | 12.7% | Polyolefin | 2 | CR95 | 49.8% |
| | PET | | | | | | (SE1013N) | | | (5.5 g/m²) |
| Example 12 | PET | 16 | Absent | — | Oxazoline | 6.4% | Polyolefin | 2 | CR95 | 49.8% |
| | | | | | | | (SE1013N) | | | (5.5 g/m²) |
| Example 13 | PET | 16 | Absent | — | Oxazoline | 6.4% | Polyolefin | 2 | CR95 | 41.1% |
| | | | | | | | (SE1013N) | | | (3 g/m²) |
| Example 14 | PET | 16 | Absent | — | Oxazoline | 6.4% | Polyolefin | 2 | CR95 | 58.6% |
| | | | | | | | (SE1013N) | | | (6 g/m²) |

| | Evaluation | | | | | | |
|---|---|---|---|---|---|---|---|
| | FR | | PCT60h | | | | |
| | EVA | | EVA | | | | |
| | adhesion | Interfacial | adhesion | Interfacial | Resistance to | | |
| | N/10 mm | detachment | N/10 mm | detachment | hydrolysis | Reflectance | Cissing |
| Example 1 | 50 | B | 20 | B | B | 82% | B |
| Example 2 | 60 | B | 30 | B | B | 82% | B |
| Example 3 | 110 | A | 100 | A | B | 82% | B |
| Example 4 | 100 | A | 60 | A | B | 82% | B |
| Example 5 | 60 | A | 50 | B | C | 82% | B |
| Comparative | 40 | C | 10 | C | B | 82% | B |
| Example 1 | | | | | | | |
| Comparative | 40 | C | 10 | C | B | 82% | B |
| Example 2 | | | | | | | |
| Comparative | 40 | C | 30 | C | B | 82% | B |
| Example 3 | | | | | | | |
| Example 6 | 60 | A | 50 | A | E | 82% | B |
| Comparative | 40 | A | 30 | C | B | 82% | B |
| Example 4 | | | | | | | |
| Comparative | 110 | A | 60 | C | B | 82% | B |
| Example 5 | | | | | | | |
| Comparative | 60 | A | 40 | C | B | 82% | B |
| Example 6 | | | | | | | |
| Example 7 | 100 | A | 60 | A | B | 82% | B |
| Example 8 | 100 | A | 60 | A | B | 82% | B |
| Example 9 | 60 | A | 30 | B | A | 82% | B |
| Example 10 | 60 | A | 30 | B | B | 92% | B |
| Example 11 | 100 | A | 90 | A | B | 82% | B |
| Example 12 | 50 | B | 20 | B | B | 82% | A |
| Example 13 | 120 | A | 120 | A | B | 70% | A |
| Example 14 | 55 | A | 50 | A | B | 82% | A |

As shown in Table 1, Examples exhibited excellent adhesiveness to EVA sealing materials. On the contrary, Comparative Examples were significantly inferior in terms of adhesive.

The entire disclosure of Japanese Patent Application No. 2011-189993 is incorporated herein by reference. All publications, patent applications, and technical standards mentioned in this specification are herein incorporated by reference to the same extent as if each individual publication, patent application, or technical standard was specifically and individually indicated to be incorporated by reference. The foregoing description of the embodiments of the invention has been provided for the purpose of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplate. It is intended that the scope of the invention be defined by the following claims and their equivalents.

1. A solar cell backsheet comprising:
a polymer base material; and
a colored layer that is disposed directly on the polymer base material, comprises a binder having an acid value of from 2 mg KOH/g to 10 mg KOH/g and a pigment at a content of from 2.5 g/m² to 8.5 g/m², and has an adhesive force of 50 N/cm or more to an ethylene-vinyl acetate sealing material.

2. The solar cell backsheet according to claim 1, wherein the colored layer further comprises a structural moiety derived from a crosslinking agent having a content of from 0.5% to 50% by mass with respect to the binder.

3. The solar cell backsheet according to claim 2, wherein the crosslinking agent is an oxazoline-based crosslinking agent or a triazine-based crosslinking agent.

4. The solar cell backsheet according to claim 1, wherein at least one layer provided on the polymer base material comprises a fluorine-based surfactant.

5. The solar cell backsheet according to claim 1, wherein the pigment is a white pigment, and a reflectance to light having a wavelength of 550 nm is 80% or more on a side where the colored layer is provided.

6. The solar cell backsheet according to claim 1, wherein when the sealing material and the colored layer are directly bonded and stored for 60 hours in an atmosphere of 120° C. and 100% relative humidity, an adhesive force between the sealing material and the colored layer after storage is 60% or more of an adhesive force between the sealing material and the colored layer before storage, and detachment between the polymer base material and the colored layer does not occur.

7. The solar cell backsheet according to claim 1, wherein the polymer base material comprises a polyester resin having a carboxyl group content of 20 equivalents/ton or less.

8. The solar cell backsheet according to claim 1, wherein the polymer base material comprises a polyester resin having a carboxyl group content of 17 equivalents/ton or less.

9. The solar cell backsheet according to claim 1, wherein the binder is constituted of a polyolefin.

10. The solar cell backsheet according to claim 1, wherein the polymer base material comprises polyethylene terephthalate and an end-capping agent in an amount of from 0.1% by mass to 10% by mass relative to a total mass of the polyethylene terephthalate.

11. The solar cell backsheet according to claim 1, wherein the polymer base material comprises inorganic particles or organic particles, the particles have an average particle size of from 0.1 μm to 10 μm, and a content of the particles is from 0% to 50% by mass relative to a total mass of the polymer base material.

12. The solar cell backsheet according to claim 10, wherein the polymer base material comprises inorganic particles or organic particles, the particles have an average particle size of from 0.1 μm to 10 μm, and a content of the particles is from 0% to 50% by mass relative to a total mass of the polymer base material.

13. The solar cell backsheet according to claim 1, wherein at least a side of the polymer base material where the colored layer is provided is surface-treated by at least one method of a corona treatment, a glow discharge treatment, or a flame treatment.

14. A solar cell module comprising:
a solar cell element;
an ethylene-vinyl acetate sealing material that seals the solar cell element;
a surface protective member that is bonded with the sealing material and protects the light-receiving surface side; and
a back surface protective member that comprises the solar cell backsheet according to claim 1, has the colored layer bonded directly with the sealing material, and protects an opposite side of the light-receiving surface.
